(19) United States
(12) Patent Application Publication
(10) Pub. No.: US 2026/0072438 A1
(43) Pub. Date: Mar. 12, 2026

(54) END-TO-END NAVIGATION USING A MULTIMODAL GENERATIVE WORLD MODEL FOR ROBOTICS SYSTEMS AND APPLICATIONS

(71) Applicant: NVIDIA Corporation, Santa Clara, CA (US)

(72) Inventors: Wei LIU, Santa Clara, CA (US); Huihua ZHAO, San Jose, CA (US); Yan CHANG, Sunnyvale, CA (US); Sida WANG, Pittsburgh, PA (US); Billy Omondi OKAL, Santa Clara, CA (US); Soha POUYA, Los Altos, CA (US); Joydeep BISWAS, Austin, TX (US)

(21) Appl. No.: 18/921,863

(22) Filed: Oct. 21, 2024

Related U.S. Application Data
(60) Provisional application No. 63/692,403, filed on Sep. 9, 2024.

(51) Int. Cl. G05D 1/60; G05D 101/15; G05D 111/10; G06V 10/82

(52) U.S. Cl. CPC G05D 1/60; G06V 10/82; G05D 2101/15; G05D 2111/10

(57) ABSTRACT

In various examples, a technique for performing end-to-end navigation using a generative world model includes converting a set of sensory inputs received by a machine at a current time step into a set of embedded features. The technique also includes generating, via execution of one or more neural networks, one or more states associated with the current time step based at least on the set of embedded features, a history of states preceding the current time step, and a first set of actions associated with a previous time step. The technique further includes converting, via execution of the one or more neural networks, the one or more states into a set of predictions associated with the current time step, and performing, by the machine, a second set of actions associated with the current time step based on the set of predictions.

### CROSS-REFERENCE TO RELATED APPLICATIONS

This application claims priority benefit of United States Provisional Patent Application titled “END-TO-END GENERALIZABLE NAVIGATION VIA WORLD MODELING,” Ser. No. 63/692,403, filed Sep. 9, 2024. The subject matter of this related application is hereby incorporated herein by reference.

### BACKGROUND

Many autonomous or semi-autonomous mobile robots or other machine types perform tasks that involve moving within large, dynamic, and/or semi-structured environments. For example, an autonomous mobile robot (AMR) may operate within a warehouse that includes (but is not limited to) items on shelves, other types of AMRs, humans, and/or human-operated equipment. These machines typically navigate to a given destination according to a route or path that accounts for factors such as (but not limited to) the time and/or distance of travel to the destination, static and moving obstacles, avoidance and/or following of other entities, traffic signs and/or rules, and/or timely execution of a task after receiving instructions for performing the task.

However, existing navigation systems for AMRs and/or other machine types tend to use complex integrations and data sharing across multiple navigation modules related to perception, planning, control, prediction, and/or other tasks, which can lead to a number of drawbacks. First, errors in one module can propagate throughout the navigation system and lead to reduced navigation performance. Second, each module includes a separate set of design and operational parameters and lacks a holistic understanding of the environment, which can limit the ability of the navigation system to make contextually aware decisions. Third, significant re-engineering and/or adjustment of individual modules is typically required to adapt the navigation system to new tasks and/or environments, which can interfere with the ability of the navigation system to scale with increasing complexity in tasks and/or environments. Fourth, the navigation system can include redundant and/or sequential processing across modules that increases latency and/or resource consumption, thereby negatively impacting the use of the navigation system in real-time and/or time-sensitive applications.

Another drawback associated with navigation and/or other tasks performed by AMRs and/or other machine types is a lack of data that can be used to train and/or evaluate modules and/or other components of the machines. For example, data associated with a specific warehouse may be collected by sensors on a robot that is manually driven around the warehouse. The collected data may then be used to operate and/or evaluate the performance of the robot within the warehouse and/or similar environments. However, the robot may be unable to generalize to other environments using the collected data. Instead, the same manual data-collection process may be repeated for each new environment (or type of environment) to adapt the robot to tasks performed within that environment (or type of environment).

As such, a need exists for more effective techniques for improving navigation and/or other tasks performed by AMRs and/or other machine types.

### BRIEF DESCRIPTION OF THE DRAWINGS

The present systems and methods for end-to-end navigation using a multimodal generative world model are described in detail below with reference to the attached drawing figures, wherein:

FIG. 1 illustrates a computing device configured to implement one or more aspects of various embodiments;

FIG. 2 illustrates a system for performing end-to-end navigation that includes the data-generation pipeline, training engine, and execution engine of FIG. 1, according to various embodiments;

FIG. 3A is a more detailed illustration of the generative world model of FIG. 2, according to various embodiments;

FIG. 3B is a more detailed illustration of an estimator model of FIG. 3A, according to various embodiments;

FIG. 4A illustrates an example set of inputs and outputs associated with the generative world model of FIG. 2, according to various embodiments;

FIG. 4B illustrates an example set of inputs and outputs associated with the generative world model of FIG. 2, according to various embodiments;

FIG. 4C illustrates an example set of inputs and outputs associated with the generative world model of FIG. 2, according to various embodiments;

FIG. 5 illustrates a flow diagram of a method for performing end-to-end navigation using a generative world model, according to various embodiments;

FIG. 6 is a more detailed illustration of the data-generation pipeline of FIG. 2, according to various embodiments;

FIG. 7 illustrates an example set of data generated by the data-generation pipeline of FIG. 2, according to various embodiments;

FIG. 8 illustrates a flow diagram of a method for generating synthetic data associated with a machine in an environment, according to various embodiments;

FIG. 9A is an illustration of an example autonomous vehicle, in accordance with some embodiments of the present disclosure;

FIG. 9B is an example of camera locations and fields of view for the example autonomous vehicle of FIG. 9A, in accordance with some embodiments of the present disclosure;

FIG. 9C is a block diagram of an example system architecture for the example autonomous vehicle of FIG. 9A, in accordance with some embodiments of the present disclosure;

FIG. 9D is a system diagram for communication between cloud-based server(s) and the example autonomous vehicle of FIG. 9A, in accordance with some embodiments of the present disclosure;

FIG. 10 is a block diagram of an example computing device suitable for use in implementing some embodiments of the present disclosure; and

FIG. 11 is a block diagram of an example data center suitable for use in implementing some embodiments of the present disclosure.

### DETAILED DESCRIPTION

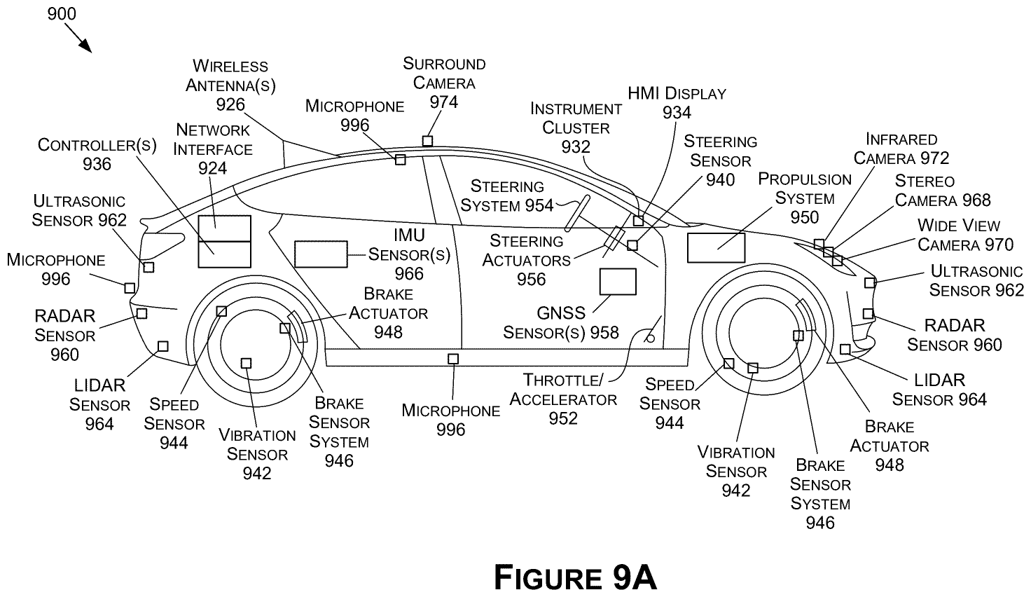

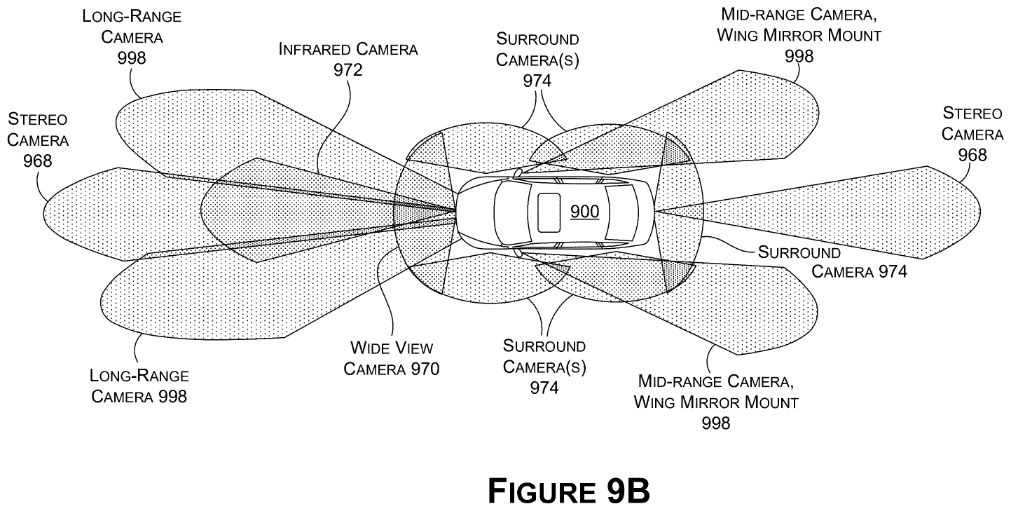

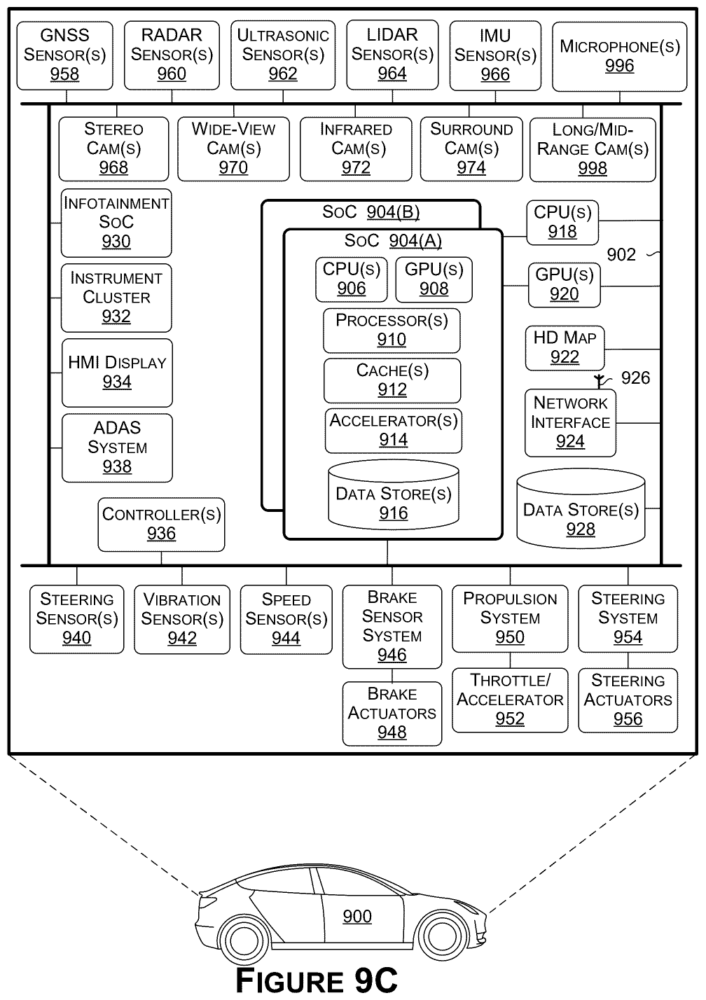

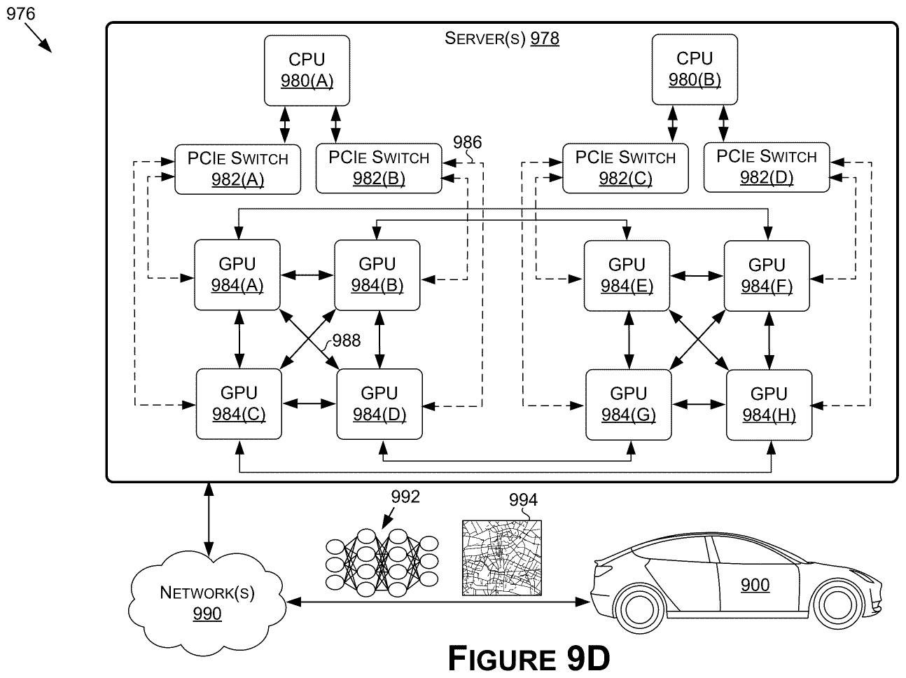

Systems and methods are disclosed related to end-to-end navigation using a multimodal generative world model for robotics systems and applications. Although the present disclosure may be described with respect to an example autonomous or semi-autonomous vehicle or machine 900 (alternatively referred to herein as “vehicle 900,” “ego-vehicle 900,” “machine 900,” or “ego-machine 900,” an example of which is described with respect to FIGS. 9A-9D), this is not intended to be limiting. For example, the systems and methods described herein may be used by, without limitation, non-autonomous vehicles or machines, semi-autonomous vehicles or machines (e.g., in one or more adaptive driver assistance systems (ADAS)), autonomous vehicles or machines, piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. As such, even though the visual within some of the figures includes a sedan-type vehicle, this is not intended to be limiting, and the components, features, and/or functionality described herein may related to any other vehicle or machine type-such as autonomous mobile robots (AMR). In addition, although the present disclosure may be described with respect to navigation in autonomous and/or semi-autonomous robots, this is not intended to be limiting, and the systems and methods described herein may be used in augmented reality, virtual reality, mixed reality, robotics, security and surveillance, autonomous or semi-autonomous machine applications, computer vision, generative modeling, and/or any other technology spaces where navigation may be used.

As discussed herein, autonomous mobile robots (AMRs) and/or other machine types tend to navigate using complex integrations across multiple navigation modules related to perception, planning, control, prediction, and/or other tasks. These navigation modules are associated with a number of drawbacks, including (but not limited to) propagation of errors across modules that lead to reduced navigation performance, a lack of holistic understanding that interferes with the ability to make contextually aware decisions, significant re-engineering and/or adjustment of individual modules to adapt the navigation system to new tasks and/or environments, and/or redundant and/or sequential processing across modules that negatively impacts the use of the navigation systems in real-time and/or time-sensitive applications.

To address the above limitations, the disclosed techniques train and execute a multimodal generative world model to perform end-to-end navigation and other tasks for an AMR and/or another type of machine. The multimodal generative world model directly maps inputs such as (but not limited to) camera images, velocities, global guidance, and/or robot states to multimodal outputs such as (but not limited to) semantic segmentations, paths, and/or navigation commands. The multimodal generative world model includes a set of encoders that convert the inputs into an embedding in a latent vector space and a feature compressor that aggregates embeddings of the inputs into a single embedded output.

The multimodal generative world model may include a posterior estimator and a prior estimator. The posterior estimator generates a latent state representing the world around the machine at a current timestep based on input that includes (i) the embedded output from the feature compressor, (ii) an action performed by the machine at a previous timestep, and/or (iii) a history of latent states up to the previous timestep. The latent state for the current timestep is converted by a set of decoders and an action policy into a semantic segmentation, perspective view, set of actions, and/or other multimodal outputs that can be used by the machine to navigate and/or perform other tasks during the current time step.

The prior estimator generates a latent state for one or more future time steps, given input that includes (i) a history that has been updated with the latent state for the current time step (e.g., from the posterior estimator) and (ii) an action associated with the current time step (e.g., as generated by an action policy from the latent state for the current time step). The latent state for a given future timestep may be converted by the set of decoders and the action policy into multimodal outputs associated with that future time step. These multimodal outputs thus represent predictions of a “future” world associated with the machine and can be used to train the multimodal generative world model and/or perform other tasks related to the predictions.

The disclosed techniques include a data-generation pipeline that generates a synthetic dataset for the purpose of training, evaluating, and/or testing the multimodal generative world model, other types of machine learning models that can be used by AMRs and/or other machine types to perform tasks, hardware configurations for the machines, and/or other components of the machines. The data-generation pipeline may include a simulator that performs various types of simulations related to a machine (e.g., a robot) navigating within an environment (e.g., a warehouse). Data generated by the simulator based on the simulations includes (but is not limited to) rendered images of the environment around the machine (e.g., from the perspective of one or more cameras on the machine and/or a birds-eye visualization), semantic labels (e.g., segmentation maps, detected objects, bounding shapes, etc.) associated with the images, a state of the machine (e.g., position, heading, velocity, etc.), and/or an occupancy map of free and/or occupied space within the environment. The data-generation pipeline may include a goal generator that determines a goal within the occupancy map, such as (but not limited to) a target location to navigate to within the environment.

The data-generation pipeline may include a planner that generates a command to the machine to take an action related to the goal, such as a linear and/or angular velocity that moves the machine toward the goal. The command is sent to the simulator, which updates the state of the machine, rendered images, semantic labels, occupancy map, and/or other data based on the action. The simulator may send some or all of the updated data to the planner to allow the planner to generate a new command based on the updated data and the goal from the goal generator. This process may repeat until the goal is reached by the machine, a certain number of time steps has been executed within the simulation, and/or another condition indicating the end of the simulation is met.

The data-generation pipeline may include a logger that records and synchronizes data outputted by the other components across time steps. For example, the logger may log data from the other components in the order in which the corresponding events occur within the simulation. The logger may also downsample some or all of the data (e.g., on a spatial and/or temporal basis) to reduce the size of the logged data.

A post-processor in the data-generation pipeline may adapt the generated data to various machine learning models and/or use cases. For example, the post-processor may resample, compress, format, and/or otherwise convert the generated data into a form that can be used to train and/or evaluate a machine learning model, hardware configuration, and/or other components of the machine.

The data-generation pipeline can be configured and/or customized via one or more sets of configuration parameters. For example, the configuration parameters may include a unique name and/or identifier for a given scenario (e.g., a combination of a particular environment, machine, goal, policy, etc.) under which data is to be generated and collected. The configuration parameters may also be used to customize the environment and/or type of machine to be simulated, the goal, the type of planner, the type of data to log, the frequency with which the data is logged, and/or the way in which the logged data is converted into a format that is suitable for training and/or evaluating a machine learning model and/or another component of the machine. Different sets of configuration parameters can be used to launch different instances of the data-generation pipeline (e.g., in parallel on multiple nodes of a distributed system) to generate data that captures different scenarios related to navigation and/or other types of tasks performed by machines in environments.

One advantage of the disclosed techniques relative to prior approaches is the ability to use a single generative world model to convert multiple sensory and/or state-based inputs associated with a machine into multimodal outputs that can be used by the machine to navigate and/or perform other tasks. The disclosed techniques may thus mitigate and/or avert issues related to conventional approaches that use complex integrations across multiple modules to perform tasks (e.g., a perception module to perceive the environment, a world model manager to generate a world model from the perceived information, a planning module to determine a plan for navigating the environment, and a control module for determining a trajectory or controls for performing the navigation), such as (but not limited to) propagation of errors across modules that lead to reduced navigation performance, a lack of holistic understanding that interferes with the ability to make contextually aware decisions, significant re-engineering and/or adjustment of multiple individual modules to adapt the navigation system to new tasks and/or environments, and/or redundant and/or sequential processing that negatively impacts the use of the navigation systems in real-time and/or time-sensitive applications. Another advantage of the disclosed techniques is the ability to generate synthetic data that spans diverse environments, goals, machine types, behaviors, and/or other types of data related to navigation and/or other tasks performed by machines. This synthetic data may be used to train, test, and/or evaluate machine learning models and/or other components of the machines, thereby facilitating fault tolerance and/or generalization of the machines to different scenarios and/or use cases.

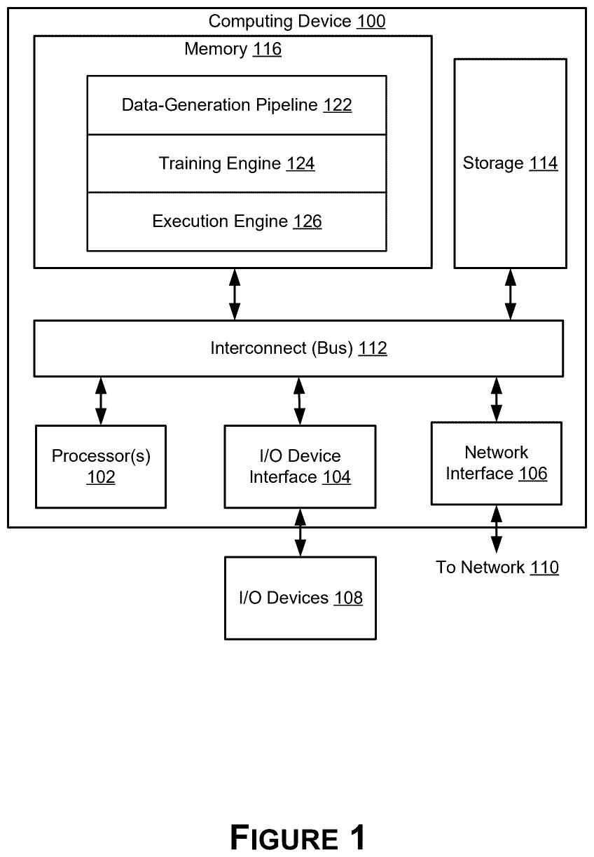

FIG. 1 is a block diagram illustrating a computing system 100 configured to implement one or more aspects of at least one embodiment. In at least one embodiment, computing system 100 may include any type of computing device, including, without limitation, a server machine, a server platform, a desktop machine, a laptop machine, a hand-held/mobile device, a digital kiosk, an in-vehicle infotainment system, a smart speaker or display, a television, and/or a wearable device. In at least one embodiment, computing system 100 is a server machine operating in a data center or a cloud computing environment that provides scalable computing resources as a service over a network.

In various embodiments, computing system 100 includes, without limitation, one or more processors 102 and one or more memories 104 coupled to a parallel processing subsystem 112 via a memory bridge 105 and a communication path 113. Memory bridge 105 is further coupled to an I/O (input/output) bridge 107 via a communication path 106, and I/O bridge 107 is, in turn, coupled to a switch 116.

In one embodiment, I/O bridge 107 is configured to receive user input information from optional input devices 108, such as (but not limited to) a keyboard, mouse, touch screen, sensor data analysis (e.g., evaluating gestures, speech, or other information about one or more uses in a field of view or sensory field of one or more sensors), a VR/MR/AR headset, a gesture recognition system, a steering wheel, mechanical, digital, or touch sensitive buttons or input components, and/or a microphone, and forward the input information to processor(s) 102 for processing. In at least one embodiment, computing system 100 may include one or more server machines in a cloud computing environment. In such embodiments, computing system 100 may omit input devices 108 and receive equivalent input information as commands (e.g., responsive to one or more inputs from a remote computing device) and/or messages transmitted over a network and received via the network adapter 118. In at least one embodiment, switch 116 is configured to provide connections between I/O bridge 107 and other components of computing system 100, such as a network adapter 118 and various add-in cards 120 and 121.

In at least one embodiment, I/O bridge 107 is coupled to a system disk 114 that may be configured to store content and applications and data for use by processor(s) 102 and parallel processing subsystem 112. In one embodiment, system disk 114 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. In various embodiments, other components, such as universal serial bus or other port connections, compact disc drives, digital versatile disc drives, film recording devices, and the like, may be connected to I/O bridge 107 as well.

In various embodiments, memory bridge 105 may be a Northbridge chip, and I/O bridge 107 may be a Southbridge chip. In addition, communication paths 106 and 113, as well as other communication paths within computing system 100, may be implemented using any technically suitable protocols, including, without limitation, AGP (Accelerated Graphics Port), HyperTransport, or any other bus or point-to-point communication protocol known in the art.

In at least one embodiment, parallel processing subsystem 112 includes a graphics subsystem that delivers pixels to an optional display device 110 that may be any conventional cathode ray tube, liquid crystal display, light-emitting diode display, and/or the like. In such embodiments, parallel processing subsystem 112 may incorporate circuitry optimized for graphics and video processing, including, for example, video output circuitry. Such circuitry may be incorporated across one or more parallel processing units (PPUs), also referred to herein as parallel processors, included within the parallel processing subsystem 112.

In at least one embodiment, parallel processing subsystem 112 incorporates circuitry optimized (e.g., that undergoes optimization) for general purpose and/or compute processing. Again, such circuitry may be incorporated across one or more PPUs included within parallel processing subsystem 112 that are configured to perform such general purpose and/or compute operations. In yet other embodiments, the one or more PPUs included within parallel processing subsystem 112 may be configured to perform graphics processing, general purpose processing, and/or compute processing operations. Memor(ies) 104 include at least one device driver configured to manage the processing operations of the one or more PPUs within parallel processing subsystem 112. In addition, memor(ies) 104 include a data-generation pipeline 122, a training engine 124, and an execution engine 126, which can be executed by processor(s) and/or parallel processing subsystem 112.

In various embodiments, parallel processing subsystem 112 may be integrated with one or more of the other elements of FIG. 1 to form a single system. For example, parallel processing subsystem 112 may be integrated with processor(s) 102 and other connection circuitry on a single chip to form a system on a chip (SoC).

Processor(s) 102 may include any suitable processor implemented as a central processing unit (CPU), a graphics processing unit (GPU), an application-specific integrated circuit (ASIC), a field programmable gate array (FPGA), an artificial intelligence (AI) accelerator, a deep learning accelerator (DLA), a parallel processing unit (PPU), a data processing unit (DPU), a vector or vision processing unit (VPU), a programmable vision accelerator (PVA) (which may include one or more VPUs, pixel processing engines (PPEs), and/or direct memory access (DMA) systems), an optical flow accelerator (OFA), any other type of processing unit, or a combination of different processing units, such as a CPU(s) configured to operate in conjunction with a GPU(s) and one or more accelerators on one or more systems on a chip (SoCs). In general, processor(s) 102 may include any technically feasible hardware unit capable of processing data and/or executing software applications. Further, in the context of this disclosure, the computing elements shown in computing system 100 may correspond to a physical computing system (e.g., a system in a data center or a machine) and/or may correspond to a virtual computing instance executing within a computing cloud.

In at least one embodiment, processor(s) 102 issue commands that control the operation of PPUs. In at least one embodiment, communication path 113 is a PCI Express link, in which dedicated lanes are allocated to each PPU. Other communication paths may also be used. The PPU advantageously implements a highly parallel processing architecture, and the PPU may be provided with any amount of local parallel processing memory (PP memory).

It will be appreciated that the system shown herein is illustrative and that variations and modifications are possible. The connection topology, including the number and arrangement of bridges, the number of processors 102, and the number of parallel processing subsystems 112, may be modified as desired. For example, in at least one embodiment, memor(ies) 104 may be connected to processor(s) 102 directly rather than through memory bridge 105, and other devices may communicate with memor(ies) 104 via memory bridge 105 and processors 102. In other embodiments, parallel processing subsystem 112 may be connected to I/O bridge 107 or directly to processor(s) 102, rather than to memory bridge 105. In still other embodiments, I/O bridge 107 and memory bridge 105 may be integrated into a single chip instead of existing as one or more discrete devices.

In certain embodiments, one or more components shown in FIG. 1 may be omitted. For example, switch 116 may be eliminated, and network adapter 118 and add-in cards 120, 121 would connect directly to I/O bridge 107. Lastly, in certain embodiments, one or more components shown in FIG. 1 may be implemented as virtualized resources in a virtual computing environment, such as a cloud computing environment. In particular, the parallel processing subsystem 112 may be implemented as a virtualized parallel processing subsystem in at least one embodiment. For example, the parallel processing subsystem 112 may be implemented as a virtual graphics processing unit(s) (vGPU(s)) that renders graphics on a virtual machine(s) (VM(s)) executing on a server machine(s) whose GPU(s) and other physical resources are shared across one or more VMs.

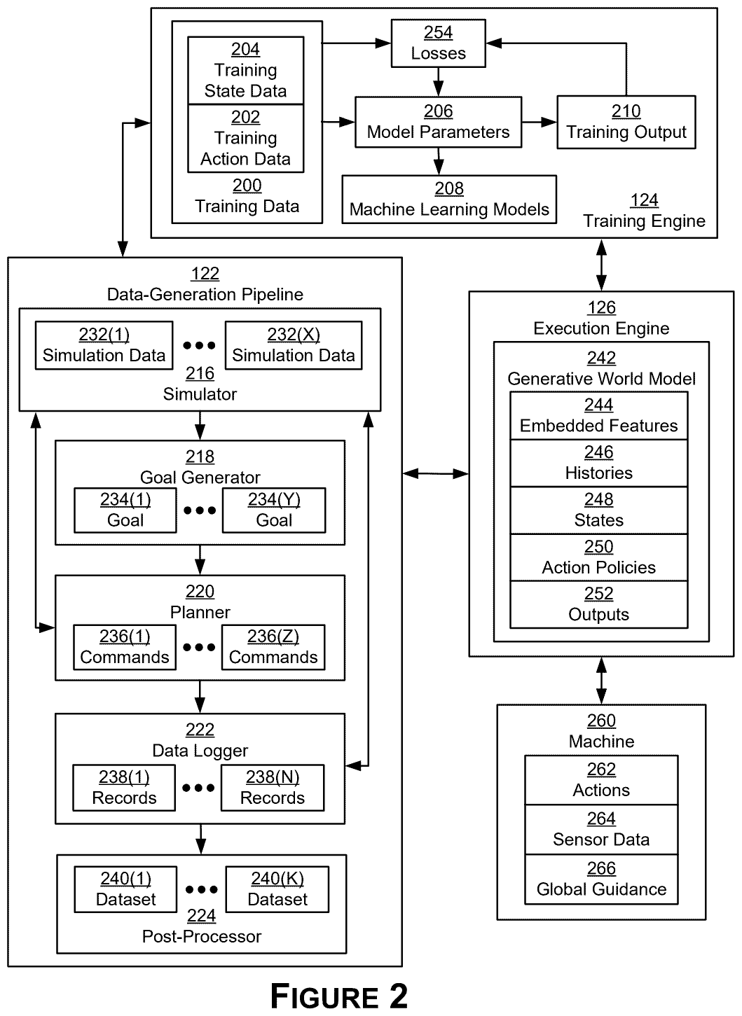

In some embodiments, training engine 124 and execution engine 126 include functionality to train and execute a multimodal generative world model to perform end-to-end navigation and/or other tasks for an AMR and/or another type of machine. The multimodal generative world model directly maps inputs such as (but not limited to) camera images, velocities, global guidance, and/or robot states to multimodal outputs such as (but not limited to) semantic segmentations, paths, and/or navigation commands. These multimodal outputs can then be used to perform navigation for the machine, generate predictions of future states associated with the machine, simulate operation of the machine, and/or perform other tasks related to the machine. Training engine 124 and execution engine 126 are described in further detail herein with respect to FIGS. 2-5.

In some embodiments, data-generation pipeline 122 generates a synthetic dataset for the purpose of training, evaluating, and/or testing the multimodal generative world model, other types of machine learning models that can be used by AMRs and/or other machine types to perform tasks, hardware configurations for the machines, and/or other components of the machines. As discussed herein, data-generation pipeline 122 may be configured and/or customized via various parameters to generate data that captures different scenarios related to navigation and/or other types of tasks performed by machines in environments. Data-generation pipeline 122 is described in further detail herein with respect to FIGS. 2 and 6-8.

FIG. 2 illustrates a system for performing end-to-end navigation that includes data-generation pipeline 122, training engine 124, and execution engine 126 of FIG. 1, according to various embodiments. As discussed herein, data-generation pipeline 122 generates synthetic data that can be used to train, evaluate, test, and/or otherwise operate a multimodal generative world model 242, other types of machine learning models that can be used by AMRs and/or other machine types to perform tasks, hardware configurations for the machines, and/or other components of the machines.

Data-generation pipeline 122 includes a simulator 216 that generates multiple sets of simulation data 232(1)-232(X) (each of which is referred to individually herein as simulation data 232). For example, simulator 216 may perform physics simulations of various environments around an AMR and/or another type of machine. During these physics simulations, simulator 216 may generate simulation data 232 that includes (but is not limited to) rendered images of the environment around the machine (e.g., from the perspective of one or more cameras on the machine and/or a birds-eye visualization), semantic labels (e.g., segmentation maps, detected objects, bounding shapes, etc.) associated with the images, a state of the machine (e.g., position, heading, velocity, etc.), and/or an occupancy map of free and/or occupied space within the environment.

Data-generation pipeline 122 includes a goal generator 218 that determines a set of goals 234(1)-234(Y) (each of which is referred to individually herein as goal 234) associated with simulation data 232. For example, goal generator 218 may generate, within a given occupancy map outputted by simulator 216, a target location to navigate to within a corresponding environment.

Data-generation pipeline 122 includes a planner 220 that generates various commands 236(1)-236(Z) that cause the machine to take one or more corresponding actions based on simulation data 232 and/or goals 234. For example, planner 220 may generate commands 236 that include (but are not limited to) a linear and/or angular velocity that move the machine toward a certain goal 234 from goal generator 218 while avoiding obstacles in an environment represented by simulation data 232 from simulator 216.

Each set of commands 236 outputted by planner 220 may be sent to simulator 216, which updates the state of the machine, rendered images, semantic labels, occupancy map, and/or other simulation data 232 based on the action. Simulator 216 may then send some or all of the updated simulation data 232 to planner 220 to allow planner 220 to generate a new set of commands 236 based on the updated simulation data 232 and the corresponding goal 234 from goal generator 218. This process may repeat until goal 234 is reached, a certain number of time steps has been executed within a given simulation, and/or another condition indicating the end of the simulation is met.

Data-generation pipeline 122 further includes a data logger 222 that aggregates simulation data 232, goals 234, commands 236, and/or other data generated by simulator 216, goal generator 218, and planner 220 into multiple records 238(1)-238(N) (each of which is referred to individually herein as record 238). For example, data logger 222 may log, in records 238, data from simulator 216, goal generator 218, and/or planner 220 in the order in which the corresponding events occur (e.g., in time steps, “frames” of simulation data 232, and/or other discrete representations of time) within the corresponding simulations. Data logger 222 may also, or instead, downsample and/or resample some or all of the data (e.g., on a spatial and/or temporal basis) in records 238 to reduce and/or modify the size of the logged data.

A post-processor 224 in data-generation pipeline 122 adapts simulation data 232, goals 234, commands 236, records 238, and/or other data generated by the other components of data-generation pipeline 122 to various machine learning models and/or use cases. For example, post-processor 224 may resample, compress, format, and/or otherwise convert data in a given set of records 238 into a form that can be used to train and/or evaluate a machine learning model, hardware configuration, and/or other components of one or more machines. Each set of records 238 that is post-processed for a given purpose and/or in a certain way may be stored in one or more datasets 240(1)-240(K) (each of which is referred to individually herein as dataset 240) for subsequent retrieval and use.

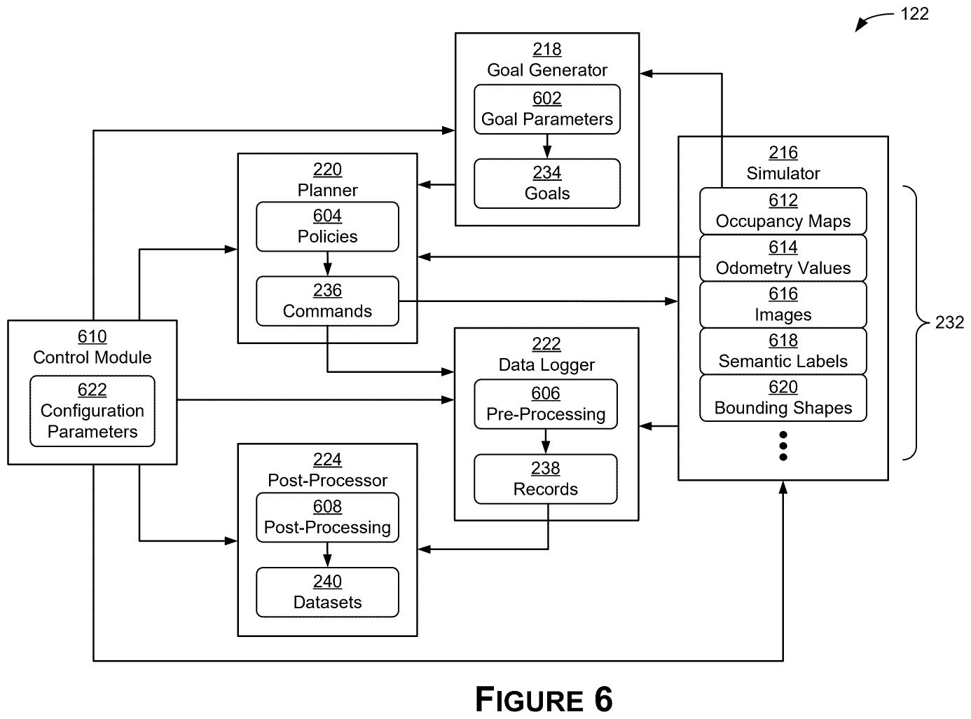

In some embodiments, data-generation pipeline 122 is configured and/or customized via different types of configuration parameters. For example, the configuration parameters may include a unique name and/or identifier for a given scenario (e.g., a combination of a particular environment, machine, goal, policy, etc.) under which data is to be generated and collected. The configuration parameters may also be used to customize the environment and/or type of machine to be simulated, the goal, the type of planner, the type of data to log, the frequency with which the data is logged, and/or the way in which the logged data is converted into a format that is suitable for training and/or evaluating a machine learning model and/or another component of the machine. Different sets of configuration parameters can be used to launch different instances of the data-generation pipeline (e.g., in parallel on multiple nodes of a distributed system) to generate data that captures different scenarios related to navigation and/or other types of tasks performed by machines in environments. Data-generation pipeline 122 is described in further detail with respect to FIGS. 6-8.

Training engine 124 trains one or more machine learning models 208 using training data 200 that is derived from one or more datasets 240 generated by data-generation pipeline 122, data collected by machines in real-world environments, simulation using, for example, the simulator 216, and/or other data sources. As shown in FIG. 2, training data 200 includes training state data 204 representing states associated with machines and/or environments. For example, training state data 204 may include sensor data (e.g., images, LiDAR, RADAR, audio data, ultrasonic data, inertial measurement unit (IMU) data, etc.) captured by virtual and/or real sensors on the machines, representations of environments around the machines (e.g., visualizations, semantic segmentations, point clouds, meshes, environment types, environment descriptions, scene description using Universal Scene Descriptor (USD) data (e.g., OpenUSD), etc.), linear and/or angular velocities of the machines, machine types and/or machine models associated with the machines, global guidance associated with navigation and/or other tasks or goals 234 of the machines, and/or other information that can be used to characterize the states of the machines and/or environments around the machines.

Training data 200 also includes training action data 202 representing actions to be performed by machines in environments. For example, training action data 202 may include “ground truth” actions, “teacher” action policies, commands, routes, trajectories, paths, and/or other indications of actions to be performed during perception, planning, control, prediction, navigation, manipulation, and/or other tasks using the machines.

In some embodiments, machine learning models 208 are used to perform and/or guide tasks using the machines. For example, machine learning models 208 may include tree-based models such as decision trees, random forests, and gradient-boosted trees; feedforward neural networks, convolutional neural networks (CNNs), recurrent neural networks (RNNs), residual neural networks, long short-term memory networks (LSTMs), graph neural networks, transformer neural networks, diffusion models, generative adversarial networks (GANs), language models (large language models (LLMs), vision language models (VLMs), multi-modal language models (MMLMs), etc.), neural rendering field (NeRF) models, and/or other types of neural networks; and/or support vector machines (SVMs), logistic regression models, hierarchical models, ensemble models, Bayesian networks, naïve Bayes classifiers, and/or other types of model architectures. Machine learning models 208 may also, or instead, include rules, filters, heuristics, logic programming, semantic nets, search techniques, named entity recognition techniques, and/or other symbolic models. Each machine learning model may be used to generate embeddings, semantic segmentations, reconstructions and/or predictions of sensor data, classification output, safety alerts, trajectories, commands, and/or other output related to one or more corresponding tasks.

During training of machine learning models 208, training engine 124 inputs some or all training state data 204 into machine learning models 208. Training engine 124 uses model parameters 206 (e.g., neural network weights) of machine learning models 208 to process the inputted training state data 204 and obtains training output 210 that includes predictions associated with training state data 204 from one or more layers, blocks, or components of machine learning models 208. Training engine 124 computes one or more losses 254 using training output 210, training state data 204, and/or training action data 202. Training engine 124 then uses a training technique (e.g., gradient descent and backpropagation) to iteratively update model parameters 206 of machine learning models 208 in a way that reduces losses 254.

In one or more embodiments, execution engine 126 uses some or all trained machine learning models 208 to implement a generative world model 242 that can be used to perform end-to-end navigation and/or other tasks for a machine 260 in a real-world, simulated, digital twin, and/or another type of environment. For example, machine 260 may include a quadruped robot, a humanoid robot, a differential drive system, an Ackermann drive system, a warehouse robot, a delivery robot, a forklift, and/or another type of AMR. Machine 260 may also, or instead, include an autonomous or semi-autonomous vehicle, drone, submarine, watercraft, and/or another type of vehicle with navigation capabilities. Generative world model 242 may be deployed for real-time inference on machine 260 using a runtime platform (e.g., NVIDIA's TensorRT) that accelerates and optimizes performance using quantization, layer and tension fusion, kernel tuning, GPU-based execution, streaming audio and/or video, and/or concurrent execution.

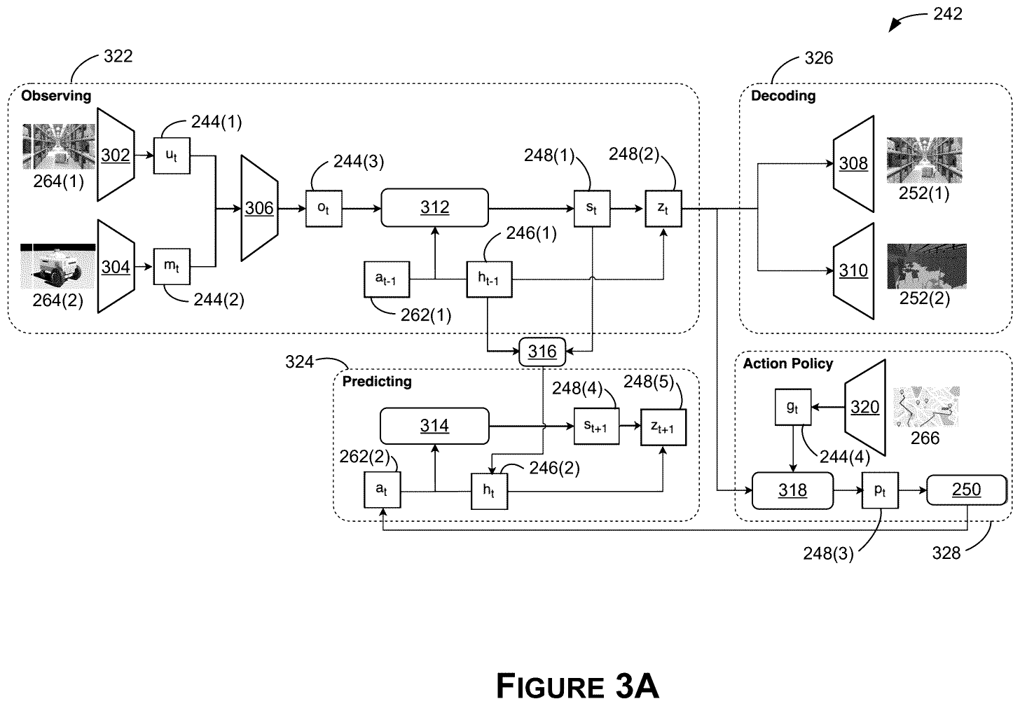

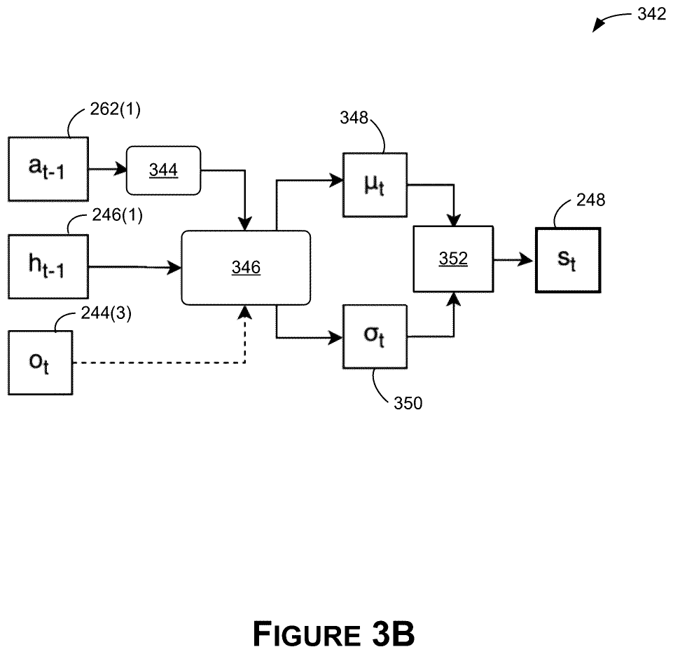

Generative world model 242 operates on inputs such as (but not limited to) sensor data 264 from machine 260 (e.g., camera images, LiDAR data, RADAR data, audio data, velocities, states, etc.), global guidance 266 associated with the tasks (e.g., paths, trajectories, routes, destinations, etc.), and/or other representations of machine 260 and/or the environment around machine 260. Given these inputs, generative world model 242 generates embedded features 244, histories 246, states 248, action policies 250, and/or outputs 252 related to machine 260 and/or the environment around machine 260. Embedded features 244, histories 246, states 248, action policies 250, and/or outputs 252 generated by generative world model 242 may additionally be used to determine one or more actions 262 to be carried out by machine 260 during execution of the tasks. Generative world model 242 is described in further detail herein with respect to FIGS. 3A-3B.

FIG. 3A is a more detailed illustration of generative world model 242 of FIG. 2, according to various embodiments. As shown in FIG. 3A, generative world model 242 includes an observing module 322, a predicting module 324, a decoding module 326, and an action policy module 328. Each of these components is described in further detail herein.

Observing module 322 iteratively generates and/or updates a set of states 246(1)-246(3) based on observations in the form of sensor data 264(1)-264(2). Within observing module 322, a first encoder 302 converts a first type of sensor data 264(1) into a first set of embedded features 244(1), and a second encoder 304 converts a second type of sensor data 264(2) into a second set of embedded features 244(2).

In one or more embodiments, encoder 302 converts sensor data 264(1) in the form of one or more images (e.g., from one or more cameras on machine 260, one or more cameras external to machine 260, a visualization that is generated by combining multiple camera views of the environment around machine 260, etc.) associated with a current time step/into a vector, matrix, and/or another set of embedded features 244(1) uₜ in a lower-dimensional latent space. Encoder 304 converts sensor data 264(2) in the form of one or more machine states (e.g., machine type, machine model, linear velocity, angular velocity, position, orientation, configuration, etc.) associated with the machine at the same time step into another vector, matrix, and/or another set of embedded features 244(1) mt in a different lower-dimensional latent space.

A feature compressor 306 converts embedded features 244(1)-244(2) into a third set of embedded features 244(3) oₜ associated with the same time step. For example, feature compressor 306 may include a neural network and/or another type of machine learning model that converts both sets of embedded features 244(1)-244(2) into a new vector, matrix, and/or another representation of embedded features 244(3) in a latent space that differs from those of embedded features 244(1)-244(2). In another example, feature compressor 306 may generate embedded features 224(3) as a concatenation, sum, average, and/or another aggregation or combination of embedded features 244(1)-244(2).

A posterior estimator 312 in observing module 322 generates a set of states 246(1)-246(2) representing the world around the machine at the current time step t. As shown in FIG. 3A, posterior estimator 312 generates a first state 248(1) sₜ based on based on input that includes (i) the set of embedded features 244(3) from the feature compressor, (ii) one or more actions 262(1) aₜ₋₁ performed by the machine at a preceding time step t−1, and (iii) a history 246(1) of latent states hₜ₋₁ up to the preceding time step. During a certain number of initial time steps in the execution of generative world model 242, state 246(1) may be generated without action 262(1) and history 246(1) because of a lack of information related to any preceding time steps. After state 246(1) is produced, state 248(1) is concatenated and/or otherwise combined with history 246(1) up to the preceding time step (e.g., if history 246(1) is available) to produce a second latent state 248(2) zₜ that is associated with the current time step and captures the “world” around the machine up to the current time step.

Decoding module 326 includes a set of decoders 308 and 310 that convert the latent state 248(2) into a set of multimodal outputs 252. More specifically, decoder 308 converts state 248(2) into a first output 252(1) that corresponds to a reconstruction of image-based sensor data 264(1). Decoder 310 converts state 248(2) into a second output 252(2) that corresponds to a semantic segmentation of the image-based sensor data 264(1). These outputs 252(1)-252(2) may be used to train components of generative world model 242 and/or perform other tasks, as discussed in further detail herein.

Action policy module 328 includes an encoder 320 that converts a route, trajectory, path, heading, and/or other global guidance 266 associated with a task to be performed by the machine into a set of embedded features 244(4) gₜ for the current time step. These embedded features 244(4) and state 248(2) for the same time step are inputted into a self-attention module 318. Self-attention module 318 converts the inputted embedded features 244(4) and state 248(2) into a fused policy state 248(3) pt. This fused policy state 248(3) is decoded by a neural network (or another type of machine learning model) implementing action policy 250 into one or more actions 262(2) for the current time step.

Predicting module 324 includes a prior estimator 314 that generates a state 248(4) sₜ₊₁ for a next time step t+1 that follows the current time step based on input that includes (i) a history 246(2) hₜ for the current time step and (ii) one or more actions 262(2) aₜ associated with the current time step (e.g., as generated by action policy module 328). History 246(2) is generated by a gated recurrent unit (GRU) 316 from input that includes history 246(1) hₜ₋₁ up to the preceding time step and state 248(1) sₜ. State 248(4) is combined (e.g., concatenated) with history 246(2) to produce a latent state 248(5) zₜ₊₁ that is associated with the next time step and represents a prediction of the “future” world around the machine at the next time step. State 248(5) can then be used to train the multimodal generative world model, decoded (e.g., using decoders 308 and/or 310 in decoding module 326) into corresponding outputs (not shown) associated with the next time steps, and/or perform other tasks related to the next time step.

The predictive process associated with predicting module 324 may be repeated for additional future time steps t+2, t+3, . . . that follow t+1. For example, state 248(4) sₜ₊₁ and history 246(2) hₜ may be processed by GRU 316 to generate an updated history 246 hₜ₊₁ for the next time step. The latent state 248(5) zₜ₊₁ may also be processed using action policy module 328 to generate a new fused policy state pₜ₊₁ for the next time step. The new fused policy state may then be converted into new set of actions aₜ₊₁ for the next time step, and the updated history and new set of actions may be used to generate a new state sₜ₊₂ and corresponding latent state zₜ₊₂ for the future time step t+2. This latent state may then be decoded by decoding module 326 into outputs 252 corresponding to future time step t+2. The process may be repeated to generate additional predictions for each subsequent future time step using states 248 associated with the preceding time step, history 246 up to the preceding time step, and actions 262 associated with the preceding time step.

In one or more embodiments, the operation of generative world model 242 is represented as a Partially Observable Markov Decision Process (POMDP), which models probabilistic belief states and solves decision-making problems by interleaving observations and actions. This POMDP may be defined by the tuple { [symbol] , [symbol] , [symbol] , T, O, R, γ}, where [symbol] represents a state space associated with one or more states 248, [symbol] denotes an action space associated with one or more actions 262, and [symbol] is an observation space associated with sensor data 264. A transition function T(s′, s, a)=Pr(s′|s, a) models the probability of transitioning to a state s′ when an action a is taken from a state s. An observation function O(o,s′,a)=Pr(o|s′,a) represents the probability of observing o after applying action a and transitioning to state s′. A reward function R(s,a) defines the reward for performing action a in state s, and γ∈[0,1) is a discount factor. A solution to the POMDP may include an optimal policy π* that maximizes the expected accumulated reward

$$E ( {\sum }_{t = 0}^{∞} {γ}^{t} R ( {a}_{t} , {s}_{t} ) ) ,$$

where sₜ and aₜ represent the state and action of machine 260 at time t.

In some embodiments, observing module 322 and predicting module 324 learn the transition function T(s′,s,a) for model prediction and the observation function O(o,s′,a) for observation correction. Action policy module 328 aims to solve the POMDP by imitating a teacher policy that closely approximates the optimal policy π*.

More specifically, prior estimator 314 learns state transitions by modeling a given state 248(4) as a normal distribution with diagonal covariance:

$${s}_{t + 1} ∼ 𝒩 ( {μ}_{θ} ( {h}_{t} , {a}_{t} ) , {σ}_{θ} ( {h}_{t} , {a}_{t} ) I ) \qquad ( 1 )$$

where the history transition is denoted by:

$${h}_{t} = {f}_{θ} ( {h}_{t - 1} , {s}_{t} ) \qquad ( 2 )$$

Posterior estimator 312 captures both state transition and observation correction, with a corresponding state 248(1) that is also estimated as a normal distribution with diagonal covariance:

$${s}_{t} ∼ 𝒩 ( {μ}_{θ} ( {h}_{t - 1} , {a}_{t - 1} , {o}_{t} ) , {σ}_{θ} ( {h}_{t - 1} , {a}_{t - 1} , {o}_{t} ) I ) \qquad ( 3 )$$

where oₜ represents embedded features 244(3) generated by encoders 302 and 304 and feature compressor 306 from sensor data 264 and/or other input observations. History 246(1) hₜ₋₁ and state 248(1) sₜ are then concatenated to form a 1-D latent state 248(2) zₜ=[hₜ₋₁, sₜ] that can be used for multi-task decoding.

In one or more embodiments, transitions that are learned by prior estimator 314 and posterior estimator 312 and represented by Equations 1-3 are modeled using neural networks. For example, f_{θ} may be implemented as GRU 316, and (μ_{θ}, σ_{θ}) in prior estimator 314 and posterior estimator 312 may include multi-layer perceptrons (MLPs). Prior estimator 314 and posterior estimator 312 are discussed in further detail herein with respect to FIG. 3B.

FIG. 3B is a more detailed illustration of an estimator model 342 of FIG. 3A, according to various embodiments. More specifically, FIG. 3B illustrates a model architecture for estimator model 342 that can correspond to posterior estimator 312 and/or prior estimator 314 of FIG. 3A.

When estimator model 342 corresponds to posterior estimator 312, one or more actions 262(1) aₜ₋₁ associated with a previous time step are processed by an MLP 344 to generate a higher-dimensional feature state. The feature state outputted by MLP 344, history 246(1) hₜ₋₁, and embedded features 244(3) oₜ for the current time step t are inputted into a normal distribution model 346 in posterior estimator 312.

Normal distribution model 346 includes an MLP that estimates a mean 348 μₜ and a standard deviation 350 σₜ for the current time step. A sampler 352 samples from the normal distribution with mean 348 and standard deviation 350 to generate a corresponding state 248 sₜ for the current time step. State 248 sₜ can then be combined with history 246(1) hₜ₋₁ to produce a corresponding latent state 248(2) zₜ, as discussed herein.

When estimator model 342 corresponds to prior estimator, one or more actions 262(1) aₜ associated with the current time step (e.g., as determined by action policy module 328 based on latent state 248(2) zₜ) are processed by MLP 344 to generate a higher-dimensional feature state. The feature state outputted by MLP 344 and history hₜ 246(2) up to the current time step are inputted into normal distribution model 346. Embedded features oₜ₊₁ for the next time step are omitted as input into normal distribution module 346 because observations for future time steps are not available. Normal distribution model 346 generates mean 348 pₜ₊₁ and standard deviation 350 σₜ₊₁ for the next time step, and sampler 352 samples from the corresponding distribution to generate a corresponding state 248 sₜ₊₁ for the next time step. The process may be repeated for additional time steps following the next time step.

Returning to the discussion of FIG. 3A, encoder 302 may correspond to a machine learning model that generates a set of embedded features 244(1) for one or more input images included in sensor data 264(1). For example, encoder 302 may include a vision transformer (ViT) (or another type of machine learning model) that is trained using self-supervised techniques. A one-dimensional vector uₜ∈ [symbol] ⁷⁶⁸ corresponding to embedded features 244(1) may be generated by concatenating a class token generated by the ViT from the input image(s) with a set of average-pooled patch tokens generated by the VIT from the input image.

Encoder may correspond to a machine learning model that generates a different set of embedded features 244(2) for one or more machine states included in sensor data 264(2). For example, encoder 304 may include a fully connected neural network (or another type of machine learning model) that converts a linear velocity, angular velocity, and/or another representation of machine state included in sensor data 264(2) into another vector mₜ∈ [symbol] ³² corresponding to embedded features 244(2).

Feature compressor 306 may include neural network layers and/or operations that concatenate and/or otherwise combine both sets of embedded features 244(1) and 244(2) into a third vector oₜ=[uₜ,mₜ] corresponding to a third set of embedded features 244(3). These embedded features 244(3) may include a latent representation of observations associated with time step t.

In some embodiments, decoders 308 and 310 generate decoded outputs 252(1) and 252(2), respectively, to ensure that the latent space associated with the latent state 248(2) zₜ captures information that can be used by machine 260 to perform navigation and/or other tasks. For example, decoder 308 may include a diffusion model (or another type of machine learning model) that reconstructs one or more input images included in sensor data 264(1). The denoising process of the diffusion model may be conditioned on the latent state 248(2) zₜ. A mean squared error (MSE) and/or another measure of differences between the input image(s) and the corresponding reconstruction(s) outputted by the diffusion model may be used to train decoder 308, posterior estimator 312, feature compressor 306, and/or encoder 302 in an end-to-end fashion.

In another example, decoder 310 may include a generative adversarial network (GAN) (or another type of machine learning model) that converts the latent state 248(2) zₜ into a semantic segmentation included in outputs 252(2). The semantic segmentation may correspond to one or more images included in sensor data 264(1), a perspective view associated with machine 260, and/or another representation of the environment around machine 260. A cross-entropy loss (or another measure of difference between the outputted semantic segmentation and a corresponding ground truth semantic segmentation of the environment) may be computed on a per-pixel basis at each upsampled resolution outputted by decoder 310. The computed loss may then be used to train decoder 310, posterior estimator 312, feature compressor 306, encoder 302, and/or encoder 304 in an end-to-end fashion.

In one or more embodiments, a Kullback-Leibler (KL) divergence is computed between a prior distribution outputted by prior estimator 314 and a corresponding posterior distribution outputted by posterior estimator 312 (e.g., for the same time step). This KL divergence may be used to train prior estimator 314 to encourage the prior distribution to match the posterior distribution, thereby allowing generative world model 242 to predict future states that align with observed data.

As discussed herein, action policy module 328 uses the latent state 248(2) zₜ and an encoded representation of global guidance 266 to generate one or more actions 262(2) aₜ˜Pr(aₜ|zₜ,gₜ). To incorporate route information, a global route included in global guidance 266 may be transformed into a local frame of reference for machine 260 and truncated into a regional route segment near machine 260. The regional route segment may then be represented as a tensor that includes a series of route poses with x and y positions.

Encoder 320 may include a VectorNet (or another type of machine learning model) that converts the tensor into a vector gₜ∈ [symbol] ⁶⁴ corresponding to embedded features 244(4). These embedded features 244(4) may capture route information associated with global guidance 266 while providing flexibility to encode additional attributes (e.g., a final destination flag) that can facilitate navigation and/or other tasks by machine 260.

Next, self-attention module 318 may fuse the latent state 248(2) zₜ and embedded features 244(4) gₜ into a policy state 248(3) pₜ. This policy state 248(3) may then be decoded by an MLP (or another type of machine learning model) implementing one or more action policies 250 into one or more actions 262(2) aₜ∈ [symbol] ⁶ that specify linear and angular speeds in the x, y, and z directions and/or a navigation path p∈ [symbol] ^{5×2} that includes five path poses in the local frame of reference for machine 260. This MLP may be trained using an L1 loss (or another measure of difference) that is computed between actions 262(2) and corresponding actions outputted by a teacher action policy (not shown) to cause the MLP to imitate the teacher action policy.

In some embodiments, generative world model 242 is trained over multiple stages. During a first training stage, action policy module 328 is omitted, and actions from the teacher action policy are used to train observing module 322, predicting module 324, and decoding module 326 using the corresponding losses. After training of observing module 322, predicting module 324, and decoding module 326 is complete (e.g., after a certain number of training steps, iterations, batches, and/or epochs have been performed; parameters of machine learning models in observing module 322, predicting module 324, and decoding module 326 converge; the losses fall below a threshold; and/or another condition is met), action policy module 328 is trained in an end-to-end fashion with observing module 322, predicting module 324, and decoding module 326 during a second training stage.

While generative world model 242 is illustrated in FIG. 3A as processing two types of sensor data 264(1)-264(2) (e.g., images and robot states) and generating two types of outputs 252(1)-252(2) (e.g., images and semantic segmentations), it will be appreciated that generative world model 242 is capable of operating using various types and/or combinations of inputs. For example, sensor data 264 associated with the environment around machine 260 may include (but is not limited to) images, depth maps, point clouds, meshes, audio data, temperature data, weather data, traffic data, and/or proximity data. In another example, sensor data 264 associated with the state of machine 260 may include (but is not limited to) accelerometer data, gyroscope data, odometer data, log data, performance data, event data, and/or error data collected by machine 260. Each type of sensor data 264 may be converted by a different encoder into a corresponding set of embedded features. Various sets of embedded features may then be further aggregated, combined, and/or otherwise processed to produce a latent representation of observations for a corresponding time step.

In another example, different types of outputs 252 may be generated by various components included in decoding module 326 and/or action policy module 328 from corresponding latent states 248 produced by observing module 322 and/or predicting module 324. These outputs 252 may include (but are not limited to) reconstructions of images, depth maps, point clouds, and/or other sensor data 264 used to produce latent states 248. These outputs may also, or instead, include (but are not limited to) semantic segmentations, detected objects and/or instances, bounding shapes, occupancy maps, paths, trajectories, linear and/or angular velocities, obstacle and/or collision avoidance actions, failure handling actions, and/or other predictions and/or actions associated with sensor data 264.

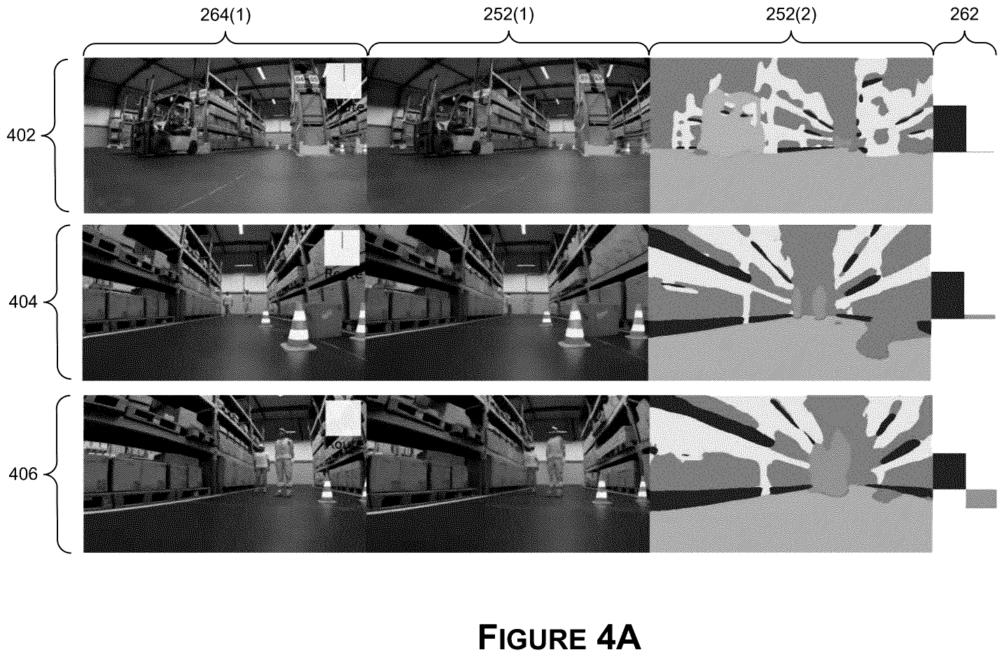

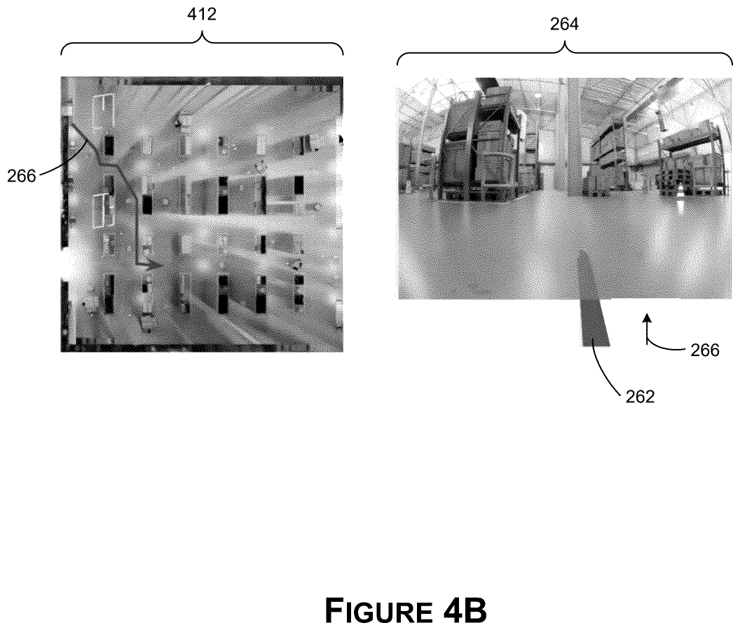

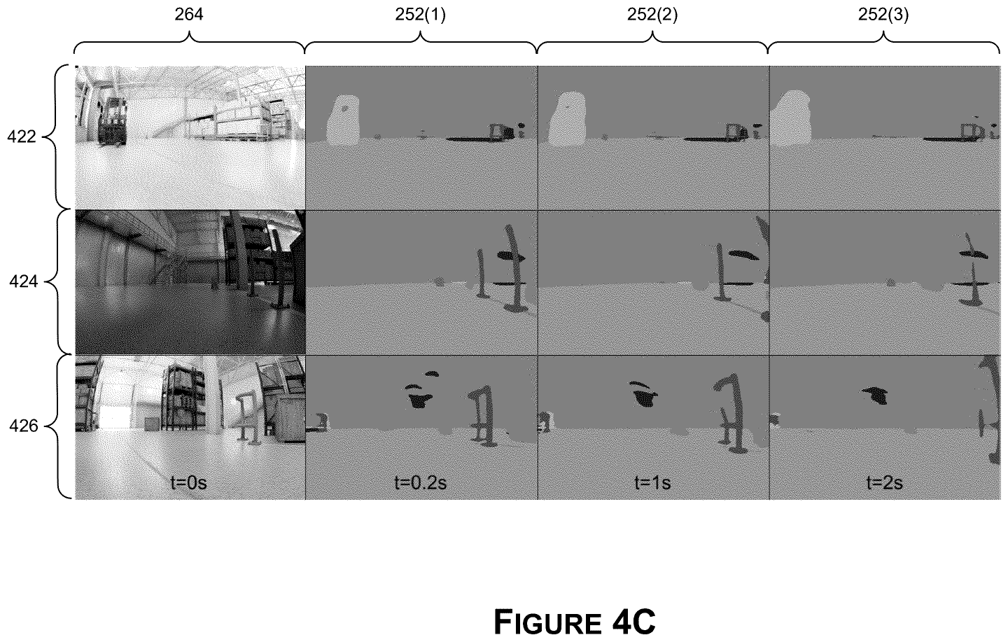

FIG. 4A illustrates an example set of inputs and outputs associated with generative world model 242 of FIG. 2, according to various embodiments. More specifically, FIG. 4A illustrates example sensor data 264(1), outputs 252(1)-252(2), and actions 262 associated with three different time steps 402, 404, and 406.

Sensor data 264(1) includes images captured by a camera on machine 260 at each time step 402, 404, 406. For example, each image may be captured by an AMR corresponding to machine 260 while the robot navigates within a warehouse environment.

Outputs 252(1) and 252(2) include reconstructions of the images and semantic segmentations associated with the images, respectively, for the same time steps 402, 404, and 406. As discussed herein, outputs 252(1)-252(2) may be generated by decoders included in generative world model 242 from latent states 248 representing sensor data 264 associated with time steps 402, 404, and 406.

Actions 262 include representations of linear velocities and angular velocities for time steps 402, 404, and 406, which can be sent to machine 260 as commands during a navigation task. The magnitudes of the linear velocities are depicted in the bars to the left, and the magnitudes and directions of the angular velocities are depicted in the bars to the right.

FIG. 4B illustrates an example set of inputs and outputs associated with generative world model 242 of FIG. 2, according to various embodiments. The inputs include global guidance 266 in the form of a route to be taken by machine 260. Global guidance 266 may be specified in the context of a birds-eye view 412 of the environment around machine 260, a map of the environment around machine 260, and/or another representation of the environment around machine 260 (e.g., when such a representation is available).

Given global guidance 266 and sensor data 264 that includes a camera view from machine 260 at a given time step, generative world model 242 generates an action 262 to be performed for that time step. Action 262 may include a linear and/or angular velocity, a path, a trajectory, and/or another indication of motion associated with machine 260. As shown in FIG. 4B, the path corresponding to action 262 differs slightly from global guidance 266. Thus, global guidance 266 may be used to inform the navigation task that is performed using generative world model 242 without requiring the navigation task to adhere strictly to the specified route.

FIG. 4C illustrates an example set of inputs and outputs associated with generative world model 242 of FIG. 2, according to various embodiments. More specifically, FIG. 4C illustrates example sensor data 264 and outputs 252(1)-252(3) associated with three different environments 422, 424, and 426 around machine 260. Sensor data 264 includes images of environments 422, 424, and 426 (e.g., as captured by a camera on machine 260). Outputs 252(1) include semantic segmentations generated by decoding latent states 248 associated with time steps that are 0.2 seconds after the times at which the corresponding images were captured. Outputs 252(2) include semantic segmentations generated by latent states 248 associated with time steps that are one second after the times at which the corresponding images were captured. Outputs 252(3)) include semantic segmentations generated by latent states 248 associated with time steps that are two seconds after the times at which the corresponding images were captured. These latent states 248 may be generated by prior estimator 314 as representations of a “future” world around machine 260 based on sensor data 264. Within the semantic segmentations, different regions may represent navigable surfaces, fences, pallets, forklifts, signs, and/or other types of objects depicted in the images.

As discussed herein, latent states 248 representing future time steps and the corresponding decoded outputs 252 may be used to train various components of generative world model 242. After training is complete, observing module 322 and action policy module 328 may be used to perform inference during a given task (e.g., navigation) by machine 260 based on sensor data 264 corresponding to observations from machine 260. Latent states 248 generated by predicting module 324 and/or corresponding outputs 252 for future time steps may be used to perform tasks such as (but not limited to) running simulations, conducting safety checks (e.g., detect and respond to potential hazards), and/or interpreting and/or explaining predictions generated by generative world model 242 and/or the behavior of machine 260.

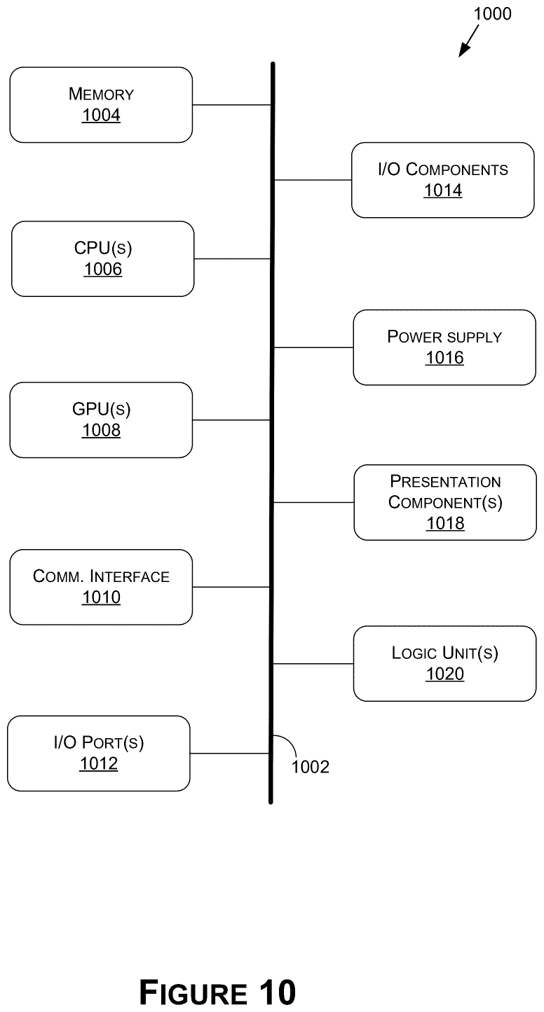

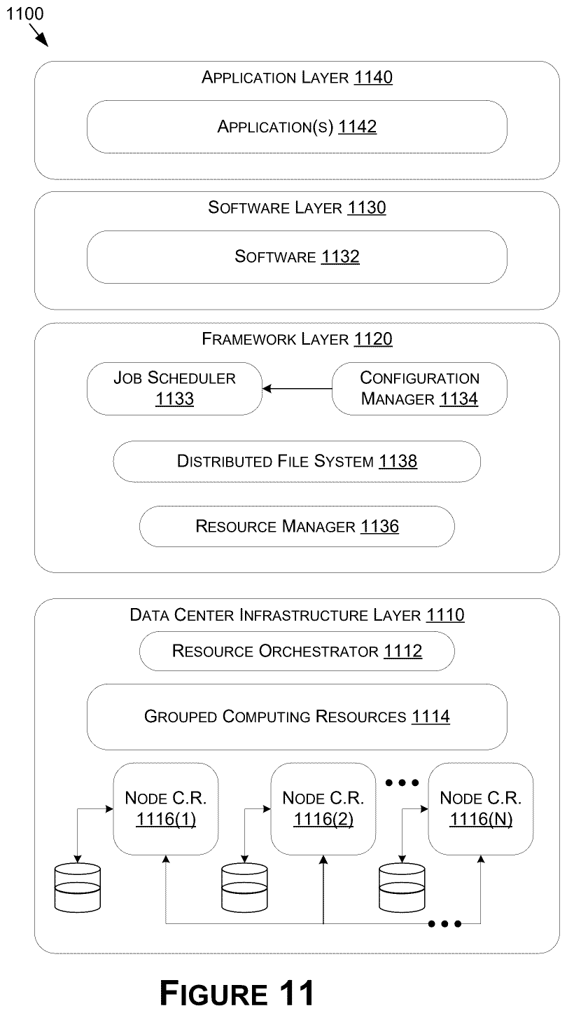

It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. In some embodiments, the systems, methods, and processes described herein may be executed using similar components, features, and/or functionality to those of example autonomous vehicle 900 of FIGS. 9A-9D, example computing device 1000 of FIG. 10, and/or example data center 1100 of FIG. 11.

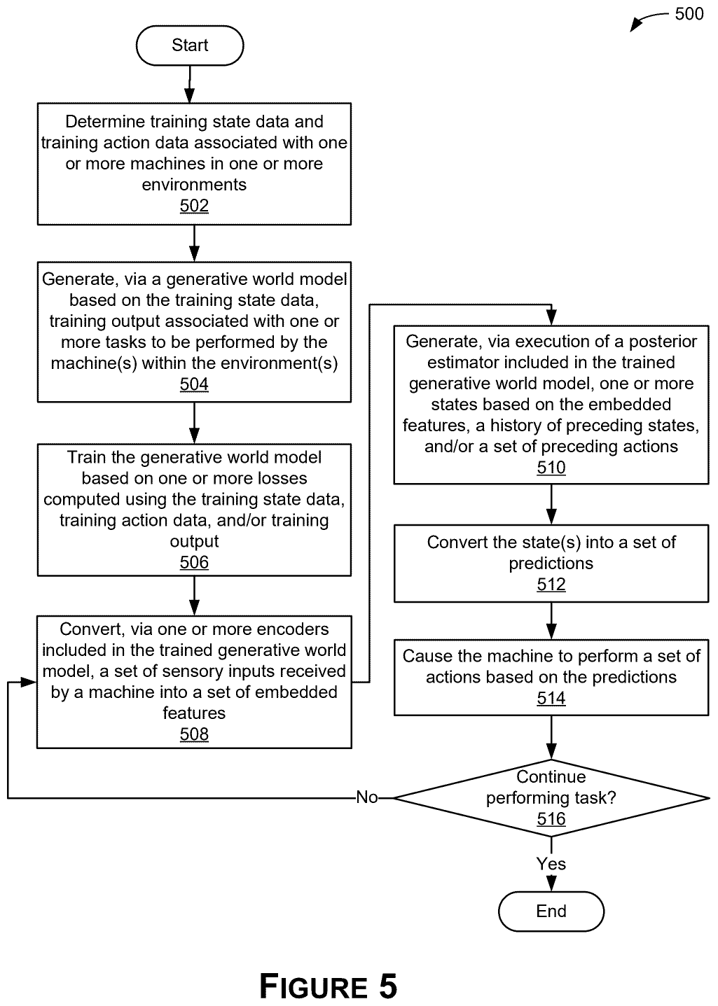

Now referring to FIG. 5, each block of method 500, described herein, comprises a computing process that may be performed using any combination of hardware, firmware, and/or software. For instance, various functions may be carried out by a processor executing instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 500 is described, by way of example, with respect to the system of FIGS. 1-2. However, this method may additionally or alternatively be executed by any one system, or any combination of systems, including, but not limited to, those described herein. Further, the operations in method 500 may be omitted, repeated, and/or performed in any order without departing from the scope of the present disclosure.

FIG. 5 illustrates a flow diagram of a method 500 for performing end-to-end navigation using a generative world model, according to various embodiments. As shown in FIG. 5, method 500 begins with operation 502, in which training engine 124 determines training state data and training action data associated with one or more machines in one or more environments. For example, training engine 124 may receive the training state data and training action from data-generation pipeline 122, one or more datasets collected from real-world machines interacting with real-world environments, one or more datasets of synthetic data, and/or other sources of data. The training state data may characterize the machine and/or the environment around the machine. The training action data may include a ground truth action policy for the machine, actions to be performed by the machine based on corresponding state data, and/or other indications of the desired behavior of the machine in performing one or more tasks.

In operation 504, training engine 124 generates, via a generative world model based on the training state data, training output associated with one or more tasks to be performed by the machine(s) within the environment(s). For example, training engine 124 may input the training state data into the generative world model. Training engine 124 may also use the generative world model to generate embedded features, states, decoded outputs, actions, and/or other training output from the inputted training state data.

In operation 506, training engine 124 trains the generative world model based on one or more losses computed using the training state data, training action data, and/or training output. Continuing with the above example, training engine 124 may compute an L1 loss, MSE, cross entropy loss, and/or another measure of difference between the decoded outputs and/or actions and the corresponding ground truth values. Training engine 124 may also, or instead, compute a KL divergence and/or another measure of difference between a posterior distribution associated with states outputted by a posterior estimator in the generative world model and a prior distribution associated with states outputted by a prior estimator in the generative world model. Training engine 124 may further update parameters of various components of the generative world model based on the corresponding losses.

As discussed herein, training engine 124 may train the generative world model over multiple training stages. During a first training stage, training engine 124 may train neural networks and/or other machine learning models included in an observing module, decoding module, and/or predicting module within the generative world model using one or more losses. After the first training stage is complete, training engine 124 may perform a second training stage that trains an action policy module in the generative world model and the observing module, decoding module, and predicting module in an end-to-end fashion using the corresponding losses.

In operation 508, execution engine 126 converts, via one or more encoders included in the trained generative world model, a set of sensory inputs received by a machine into a set of embedded features. For example, execution engine 126 may use a different encoder to convert each type of sensory input into a corresponding set of embedded features in a lower-dimensional latent space. Execution engine 126 may also use a feature compressor to aggregate and/or otherwise combine multiple sets of embedded features corresponding to multiple types of sensory inputs into a single set of embedded features representing all observations made by the machine for a current time step.

In operation 510, execution engine 126 generates, via execution of a posterior estimator included in the trained generative world model, one or more states based on the embedded features, a history of preceding states, and/or a set of preceding actions. For example, execution engine 126 may initially (e.g., during each time step included in a certain number of starting time steps) convert only the embedded features into a latent state.

In operation 512, execution engine 126 converts the state(s) into a set of predictions. Continuing with the above example, execution engine 126 may use the decoding module in the trained generative world model to convert the latent state into a reconstruction of an image, point cloud, and/or another representation of the environment around the machine. Execution engine 126 may also, or instead, use the decoding module and/or action policy module to convert the latent state into a semantic segmentation, set of actions, and/or another type of prediction associated with the machine and/or environment.

In operation 514, execution engine 126 causes the machine to perform a set of actions based on the predictions. Continuing with the above example, execution engine 126 may transmit the predicted actions as commands related to linear velocity, angular velocity, and/or other types of motion (e.g., forward motion, backward motion, left turn, right turn, etc.) to the machine. The transmitted commands may be executed by the machine to advance the machine in performing the task.

In operation 516, execution engine 126 decides whether or not to continue perform a task using the machine and/or trained generative world model. For example, execution engine 126 may determine that a navigation (or another type of) task should continue to be performed using the machine and/or trained generative world model while the task is not complete and/or while a certain amount of time has not yet elapsed since the task was assigned to the machine. While execution engine 126 determines that the task should continue being performed, execution engine 126 repeats operations 508, 510, 512, and 514 to generate additional states, predictions, and/or actions for subsequent time steps. After a certain number of time steps have passed, execution engine 126 may perform operation 510 by generating state(s) associated with a current time step using a history of preceding states up to a preceding time step, a set of preceding actions associated with the preceding time step, and a set of embedded features associated with the current time step. Execution engine 126 also performs operation 516 after a certain number of time steps and/or according to another frequency to determine whether or not to continue performing the task. Execution engine 126 thus uses the generative world model and machine to perform the task until the task is complete, the task has “timed out,” and/or another condition is met.

FIG. 6 is a more detailed illustration of data-generation pipeline 122 of FIG. 2, according to various embodiments. As discussed herein, data-generation pipeline 122 generates synthetic data that can be used to train, evaluate, test, simulate, and/or otherwise operate generative world model 242, other types of machine learning models that can be used by AMRs and/or other machine types to perform tasks, hardware configurations for the machines, and/or other components of the machines.

Within data-generation pipeline 122, simulator 216 generates and/or updates simulation data 232 related to one or more machines and/or one or more environments around the machine(s). As shown in FIG. 6, simulation data 232 may include (but is not limited to) occupancy maps 612, odometry values 614, images 616, semantic labels 618, and/or bounding shapes 620 (e.g., boxes, squares, rectangles, polygons, etc.).

Occupancy maps 612 include representations of empty and occupied space within the environments. For example, an occupancy map associated with a given simulation may include a two-dimensional (2D) and/or three-dimensional (3D) grid representing the environment around a machine. Within the grid, each cell may be associated with a binary value indicating whether or not the corresponding region of space is occupied (e.g., by an obstacle, object, etc.). Each cell may also, or instead, be associated with a probability of the corresponding region of space being occupied. Each cell may also, or instead, be associated with a numeric “cost” that quantifies the difficulty in moving within the corresponding region of space. Occupancy maps 612 may also, or instead, include and/or be substituted with point clouds, meshes, and/or other representations of “occupied space” in the environments.

Odometry values 614 include numeric values associated with motion by the machines. For example, odometry values 614 for a machine within a given simulation may indicate a distance traveled by the machine, the position of the machine, the heading of the machine, the linear and/or angular velocity of the machine, the linear and/or angular acceleration of the machine, and/or other information that can be used to derive and/or estimate a position and/or orientation of the machine within a corresponding environment.

Images 616 include visual representations of the environments around the machines. For example, images 616 may depict the environments from the perspectives of cameras and/or other sensor modalities on the machines. Images 616 may also, or instead, include birds-eye views of the environments, perspective views of the environments, 360-degree visualizations of the environments, and/or other depictions of the environments that are external to the machines and/or individual cameras on the machines. Images 616 may include per-pixel color values, depth values, normal values, motion vectors (e.g., between consecutive frames of video), LiDAR intensity values, and/or other types of information that can be used to characterize the environments.

Semantic labels 618 include indications of classes, objects, and/or other properties that assist with understanding of the environments. For example, semantic labels 618 may include semantic segmentations that label individual pixels within images 616, points within point clouds, polygons within meshes, and/or other representations of the environments with the corresponding classes. Semantic labels 618 may also, or instead, identify objects, instances of objects, and/or other entities that are found within individual images, point clouds, meshes, and/or other representations of the environments.

Bounding shapes 620 include representations of the locations and/or sizes of objects within the environments. For example, bounding shapes 620 may include rectangular outlines for the objects within images 616. Bounding shapes 620 may also, or instead, include parallelepiped outlines for the objects within point clouds and/or other 3D representations of the environments. Each bounding shape may be associated with a class label, instance, and/or another indication of a corresponding object.

In one or more embodiments, simulator 216 generates at least a portion of simulation data 232 using physics simulations and/or photorealistic renderings of the machines and/or environments. These physics simulations and/or photorealistic renderings may be performed using a physically-based virtual environment such as NVIDIA Isaac Sim (NVIDIA Isaac Sim™, NVIDIA Isaac Gym™, and/or NVIDIA Drive Sim™, which are registered trademarks of NVIDIA Corporation) that is built on an NVIDIA Omniverse (NVIDIA Omniverse Sim™ is a registered trademark of NVIDIA Corporation) platform. The simulation environment may support loading of robot models (e.g., quadruped robots, humanoid robots, differential drive systems, Ackermann drive systems, forklifts, etc.) and/or sensors (e.g., cameras, LiDAR, IMUs, etc.), randomization of environments and/or environmental attributes (e.g., lighting, reflection, color, position, etc.), addition of objects to the environments, and/or the specification of physics, material, and/or collision properties of the objects.

As discussed herein, generator 218 determines one or more goals 234 associated with simulation data 232. For example, goal generator 218 may generate, within a given occupancy map outputted by simulator 216, a target location to navigate to within a corresponding environment.

In some embodiments, goal generator 218 generates some or all goals 234 based on corresponding goal parameters 602. For example, goal parameters 602 may specify that navigation-based goals are to be randomly sampled from the navigable free space within occupancy maps 612 generated by simulator 216. Goal parameters 602 may also, or instead, specify one or more regions within occupancy maps 612 from which goals 234 are to be preferentially sampled and/or attributes of these regions (e.g., regions with more “detail” and/or obstacles). Goal generator 218 may use these goal parameters 602 to sample goals 234 more frequently from the corresponding regions, thereby increasing coverage of tasks associated with the regions in the synthetic data.

Planner 220 uses one or more policies 604 to generate commands 236 that instruct machines in simulations performed by simulator 216 to perform actions related to goals 234. For example, planner 220 may implement and/or carry out action policies 604 that generate commands 236 based on goals 234 from goal generator 218 and odometry values 614 and/or other information from simulator 216. Each policy may include a planning stack, teacher policy, and/or another component that generates commands 236 to operate a machine based on a state of the machine and/or the environment around the machine. These commands 236 may (but are not limited to) a linear and/or angular velocity, trajectory, path, and/or another indication of motion that advances a machine toward a certain goal 234 from goal generator 218 while avoiding obstacles in a corresponding simulated environment.

Each set of commands 236 outputted by planner 220 may be sent to simulator 216, which updates simulation data 232 based on the corresponding action. For example, planner 220 may generate a given set of commands 236 based on simulation data 232 associated with a given time step in a simulation. These commands 236 may be transmitted to simulator 216, which generates updated simulation data 232 for the next time step. This simulation data 232 for the next time step may reflect changes to the machine and/or environment after the machine performs actions corresponding to commands 236. Simulator 216 may then send some or all of the updated simulation data 232 to planner 220 to allow planner 220 to generate a new set of commands 236 based on the updated simulation data 232 and the corresponding goal 234 from goal generator 218. This process may repeat until goal 234 is reached, a certain number of time steps has been executed within the simulation, and/or another condition indicating the end of the simulation is met.

Data logger 222 aggregates simulation data 232, goals 234, commands 236, and/or other data generated by simulator 216, goal generator 218, and planner 220 into records 238 of events associated with the corresponding time steps. For example, simulator 216, goal generator 218, and/or planner 220 may include and/or be associated with nodes that implement publishers in a publish-subscribe messaging system such as Robot Operating System (ROS). Each publisher may publish messages and/or events associated with a corresponding component of data-generation pipeline 122 (e.g., simulator 216, goal generator 218, planner 220, etc.) to one or more topics. Data logger 222 may include and/or be associated with nodes that implement subscribers to these topic(s) within the publish-subscribe messaging system. Each subscriber may receive messages from one or more corresponding topics. Data logger 222 may log data from the received messages by pre-processing 606 the data and storing the pre-processed data in records 238.

In one or more embodiments, pre-processing 606 includes determining an order in which data and/or events occur within a given simulation; generating records 238 that span a certain time interval and/or at a certain frequency; downsampling some or all of the logged data; and/or other data-processing operations associated with data from simulator 216, goal generator 218, and/or planner 220. For example, data logger 222 may synchronize data that is published at different frequencies by simulator 216, goal generator 218, and planner 220 by associating the published data with individual “frames” of time, time intervals, time steps, and/or other discrete measures of time within each simulation. Data logger 222 may also store the data associated with each discrete measure of time in one or more records corresponding to that measure of time. In another example, data logger 222 may downsample images 616, semantic labels 618, bounding shapes 620, and/or other high-resolution data from simulator 216 prior to storing the data in records 238. In a third example, data logger 222 may store records 238 associated with a given scenario (e.g., a combination of a particular environment, machine, goal, policy, simulation, etc.) with a path and/or directory corresponding to the scenario. Data logger 222 may also, or instead, associate individual records 238 with unique identifiers and/or names for the corresponding scenarios.

In some embodiments, data logger 222 generates visualizations and/or charts of data in records 238 as records 238 are created. For example, data logger 222 may output, in a graphical user interface, images 616, semantic labels 618, bounding shapes 620, occupancy maps 612, odometry values 614, and/or other visual representations of simulation data 232. Data logger 222 may also, or instead, output “map pins,” routes, and/or other representations of goals 234 and/or guidance related to goals 234 within the corresponding occupancy maps 612, birds-eye views of environments in simulations, and/or other visual depictions of the environments. Data logger 222 may also, or instead, output paths, trajectories, and/or other visual representations of commands 236 and/or actions performed based on commands 236 as overlays on images 616, maps, and/or other representations of the environments. This outputted information may allow users to visually review the logged data, determine whether or not the logged data accurately reflects the corresponding scenarios, and/or determine whether or not the logged data can be used with various use cases and/or applications.

Post-processor 224 performs post-processing 608 that adapts records 238 and/or other data generated by the other components of data-generation pipeline 122 to various machine learning models and/or use cases. For example, post-processor 224 may resample, compress, smooth, format, and/or otherwise convert data in a given set of records 238 into a form (e.g., file format, schema, etc.) that can be used to train, test, and/or evaluate a machine learning model, hardware configuration, digital twin, and/or other components of a physical and/or virtualized machine. Post-processor 224 may also, or instead, store each set of records 238 that has been post-processed for a given purpose and/or in a certain way in one or more corresponding datasets 240.

In some embodiments, post-processor 224 generates and stores metadata that is associated with logged data in datasets 240. For example, post-processor 224 may store, in associated with a dataset for a given scenario, a number of instances of object types (e.g., forklifts, shelves, people, etc.) in the scenario, time intervals between consecutive frames represented by records 238 in the dataset, a distance covered by a machine in the scenario, a distribution of actions performed by the machine, and/or other metrics and/or statistics associated with the simulated operation of the machine in the scenario. In another example, post-processor 224 may specify, in metadata for a given dataset, goal parameters 602, policies 604, pre-processing 606 and/or post-processing 608 techniques, and/or other types of configuration parameters 622 used to generate the dataset.

In some embodiments, some or all components of data-generation pipeline 122 are configured and/or customized via configuration parameters 622 provided by a control module 610. For example, configuration parameters 622 may specify a machine type and/or model, an initial pose for the machine, a scene, one or more objects within the scene, properties of the objects, and/or other information that can be used by simulator 216 to conduct simulations. Configuration parameters 622 may also, or instead, include goal parameters 602 that are used to control the generation of goals 234 by goal generator 218. These goal parameters 602 may specify the types of goals 234 to be generated (e.g., location-based goals, tasks, etc.), sampling techniques used to generate goals 234, regions within environments from which goals 234 are to be preferentially sampled, attributes of regions within environments from which goals 234 are to be preferentially sampled, weights and/or other measures of importance associated with sampling goals 234 from various regions within the environments, times at which one or more new goals 234 are to be sampled (e.g., after one or more existing goals 234 have been reached), and/or other parameters that can be used to control and/or modify the generation of goals 234 by goal generator 218. Configuration parameters 622 may also, or instead, include specific policies 604 to be used by planner 220 in generating commands 236, behavioral attributes (e.g., a level of aggressiveness and/or conservatism in performing a task and/or reaching a goal; types of commands 236 to be generated; minimum, maximum, and/or valid values associated with commands 236; etc.) associated with those policies 604, text- and/or code-based instructions for policies 604, platforms and/or frameworks used to implement policies 604, and/or other information that can be used to implement policies 604 and/or generate commands 236. Configuration parameters 622 may also, or instead, include parameters related to publishing and/or subscribing to topics by components of data-generation pipeline 122. Configuration parameters 622 may also, or instead, include identifiers, paths, logging frequencies, downsampling parameters, resampling parameters, file formats, schemas, visualization types, and/or other information that can be used to perform pre-processing 606 and/or post-processing 608 associated with data in records 238 and/or datasets 240.

Configuration parameters 622 may be defined and/or updated using various techniques. For example, configuration parameters 622 may be provided by one or more users via one or more configuration files, application programming interfaces (APIs), user interfaces, and/or other mechanisms. Some or all configuration parameters 622 may also, or instead, be randomly generated (e.g., by sampling from distributions, ranges, and/or sets of valid configuration parameters 622). Some or all configuration parameters 622 may also, or instead, be generated and/or updated using machine learning, optimization, and/or search techniques (e.g., to increase coverage of environments and/or scenarios by datasets 240 and/or generate synthetic data related to specific environments and/or scenarios). Control module 610 may transmit configuration parameters 622 to simulator 216, goal generator 218, planner 220, data logger 222, and/or post-processor 224. Control module 610 may also, or instead, configure the operation of simulator 216, goal generator 218, planner 220, data logger 222, and/or post-processor 224 using the corresponding configuration parameters 622.

In some embodiments, configuration parameters 622 include a unique name and/or identifier for a given scenario (e.g., a combination of a particular environment, machine, goal, policy, etc.) under which data is to be generated and collected. Configuration parameters 622 may also be used to customize and/or randomize the environment and/or type of machine to be simulated, the goal, the type of policy, the type of data to log, the frequency with which the data is logged, and/or the way in which the logged data is converted into a format that is suitable for training and/or evaluating a machine learning model and/or another component of the machine.

In some embodiments, different sets of configuration parameters 622 are used to launch different instances of data-generation pipeline 122 to generate data that depicts different scenarios related to navigation and/or other types of tasks performed by machines in environments. For example, multiple instances of data-generation pipeline 122 may be launched in parallel on multiple nodes of a cloud computing system using an NVIDIA One-system-to-many-others (OSMO) workflow. Each instance may be used to generate and/or collect simulation data 232, goals 234, commands 236, records 238, and/or datasets 240 associated with a given scenario and/or set of scenarios. The number of instances of data-generation pipeline 122 and/or the number of nodes on which a given instance of data-generation pipeline 122 is deployed may be scaled to accommodate requirements and/or preferences associated with the amount of synthetic data to generate; applications and/or use cases associated with the synthetic data; coverage of environments, machines, policies 604, goals 234, and/or scenarios associated with the synthetic data; and/or other factors. Additional OSMO workflows may also be used to launch pipelines that are used to train, test, and/or evaluate machine learning models, policies, hardware configurations, software stacks, twins, and/or other components or representations of machines using the generated simulation data 232, goals 234, commands 236, records 238, and/or datasets 240.

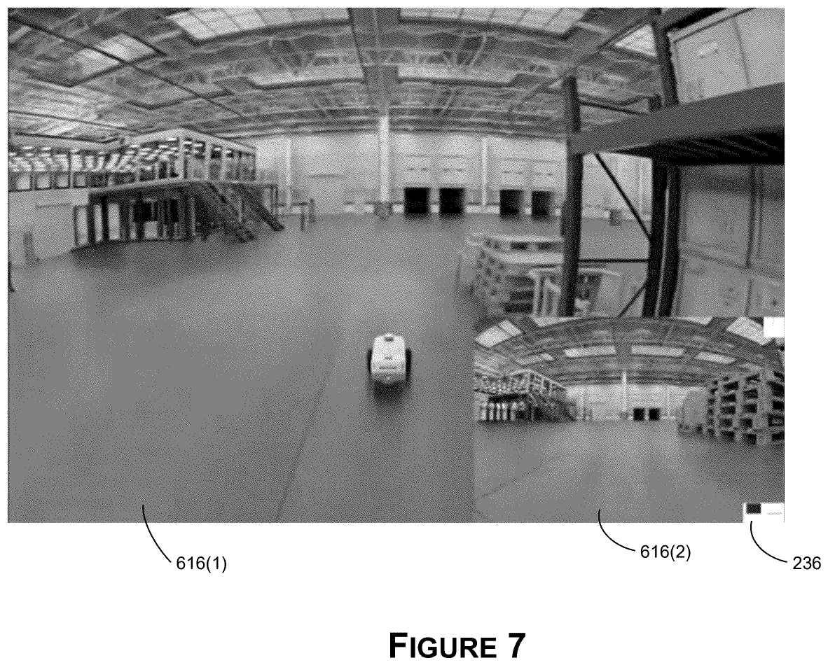

FIG. 7 illustrates example synthetic data generated by data-generation pipeline 122 of FIG. 2, according to various embodiments. As shown in FIG. 7, the synthetic data includes two images 616(1)-616(2) that depict a warehouse environment around a machine at a given time step within a simulation. Image 616(1) includes a perspective view of the environment from a point that is behind the machine, and image 616(2) includes a view from a camera on the machine. These images 616(1)-616(2) may be rendered by simulator 216 based on a 3D scene representing the environment, odometry values 614 associated with the machine at the time step, and/or other simulation data 232.

The synthetic data also includes a set of commands 236 associated with the same time step. These commands 236 include a linear velocity with a magnitude that is depicted in the bar to the left and an angular velocity with a magnitude and direction that are depicted in the bar to the right. These commands 236 may be used to update the state of the robot and/or the environment within the simulation. The updated state(s) may then be used to generate new images 616, other simulation data 232, and/or commands 236 for the next time step in the simulation.

It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. In some embodiments, the systems, methods, and processes described herein may be executed using similar components, features, and/or functionality to those of example autonomous vehicle 900 of FIGS. 9A-9D, example computing device 1000 of FIG. 10, and/or example data center 1100 of FIG. 11.

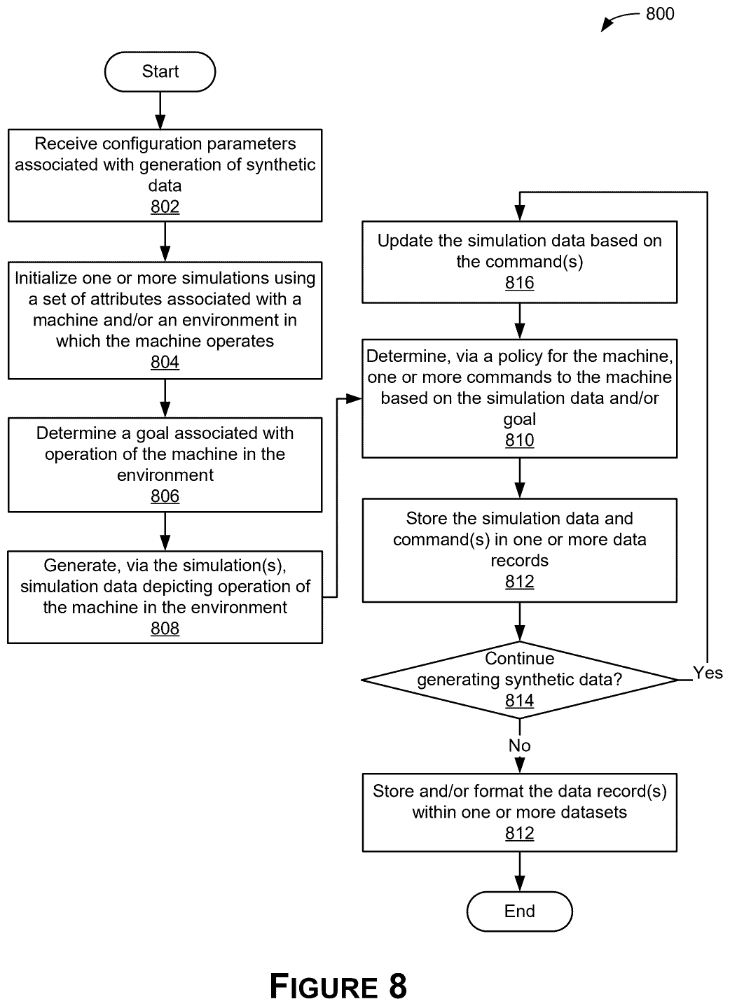

Now referring to FIG. 8, each block of method 800, described herein, comprises a computing process that may be performed using any combination of hardware, firmware, and/or software. For instance, various functions may be carried out by a processor executing instructions stored in memory. The methods may also be embodied as computer-usable instructions stored on computer storage media. The methods may be provided by a standalone application, a service or hosted service (standalone or in combination with another hosted service), or a plug-in to another product, to name a few. In addition, method 800 is described, by way of example, with respect to the systems of FIGS. 1 and 6. However, these methods may additionally or alternatively be executed by any one system, or any combination of systems, including, but not limited to, those described herein.

FIG. 8 illustrates a flow diagram of a method 800 for generating synthetic data associated with a machine in an environment, according to various embodiments. As shown in FIG. 8, method 800 begins with operation 802, in which data-generation pipeline 122 receives configuration parameters associated with generation of the synthetic data. For example, data-generation pipeline 122 may receive the configuration parameters via one or more configuration files, API calls, and/or user interfaces. The configuration parameters may be used to configure and/or customize the generation of the synthetic data. For example, the configuration parameters include a unique name and/or identifier for a given scenario (e.g., a combination of a particular environment, machine, goal, policy, etc.) under which data is to be generated and collected. The parameters may also be used to customize the environment and/or type of machine to be simulated, the goal, the policy, the type of data to log, the frequency with which the data is logged, and/or the way in which the logged data is converted into a format that is suitable for training and/or evaluating a machine learning model and/or another component of the machine.

In operation 804, data-generation pipeline 122 initializes one or more simulations using a set of attributes associated with the machine and/or the environment in which the machine operates. For example, data-generation pipeline 122 may use the configuration parameters to determine and/or randomize the machine type, machine model, and/or initial pose of the machine in the environment. Data-generation pipeline 122 may also, or instead, obtain, generate, and/or randomize a 3D scene corresponding to the environment and/or an occupancy map of the 3D scene. Data-generation pipeline 122 may also, or instead, add one or more objects to the 3D scene and/or set physics, material, and/or collision properties of the object(s).

In operation 806, data-generation pipeline 122 determines a goal associated with operation of the machine in the environment. For example, data-generation pipeline 122 may generate a navigation-based goal by sampling a location to which the machine is to navigate within the environment from unoccupied space within the environment. This sampling may be performed preferentially for certain regions within the environment that are specified in the configuration parameters and/or for certain regions with attributes that are specified in the configuration parameters.

In operation 808, data-generation pipeline 122 generates, via the simulation(s), simulation data depicting the operation of the machine in the environment. For example, data-generation pipeline 122 may render one or more images of the environment from the perspective of one or more cameras on the machine, one or more locations that are external to the machine, and/or other viewpoints. Data-generation pipeline 122 may also, or instead, generate point clouds, IMU measurements, and/or other sensor measurements associated with sensors on the machine.

In operation 810, data-generation pipeline 122 determines, via a policy for the machine, one or more commands to the machine based on the simulation data and/or goal. For example, data-generation pipeline 122 may input the simulation data and/or goal into a planning stack, neural network, and/or another component implementing the policy. Given the inputted data, the component may generate commands that specify linear and/or angular velocities for the machine. The component may also, or instead, generate one or more distributions of commands from which the command(s) are sampled.

In operation 812, data-generation pipeline 122 stores the simulation data and command(s) in one or more data records. For example, data-generation pipeline 122 may associate the simulation data generated in operation 808 and the commands generated in operation 810 with the same time step and/or “frame” within the simulation(s). Data-generation pipeline 122 may also log the simulation data and command(s) in one or more data records associated with the time step and/or frame.

In operation 814, data-generation pipeline 122 determines whether or not to continue generating synthetic data. For example, data-generation pipeline 122 may determine that generation of synthetic data is to continue until the goal is reached by the machine, the simulation(s) have run for a certain number of time steps, and/or another condition is met. If data-generation pipeline 122 determines that generation of synthetic data is to continue, data-generation pipeline 122 performs operation 816, in which data-generation pipeline updates the simulation data based on the command(s). For example, data-generation pipeline 122 may update the position, heading, velocity, and/or another state of the machine to reflect execution of the command(s) by the machine. Data-generation pipeline 122 may also, or instead, generate new images and/or sensor data that reflect the updated machine state.

Data-generation pipeline 122 then repeats operation 810 to generate new commands based on the updated simulation data. Data-generation pipeline 122 similarly repeats operation 812 to store the updated simulation data and command(s) in one or more additional data records. For example, data-generation pipeline 122 may store the updated simulation data and command(s) in association with a new (e.g., incremented) time step and/or frame. After a given set of simulation data and command(s) has been stored in one or more data records, data-generation pipeline 122 repeats operation 814 to determine whether or not to continue generating synthetic data.

After data-generation pipeline 122 determines in operation 814 that generation of synthetic data is to be discontinued, data-generation pipeline 122 performs operation 816, in which data-generation pipeline 122 stores and/or formats the data record(s) within one or more datasets. For example, data-generation pipeline 122 may generate a different dataset for each use case and/or application associated with the synthetic data. Within a given dataset, data-generation pipeline 122 may resample, format, and/or otherwise post-process the corresponding data records to adapt the data records to the corresponding use case and/or application. Data-generation pipeline 122 may then provide the dataset for use in training, testing, and/or evaluating machine learning models, hardware configurations, policies, digital twins, and/or other components and/or representations of machines in various environments.

The systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, generative AI, light transport simulation (e.g., ray-tracing, path tracing, etc.), collaborative content creation for 3D assets, systems for performing generative AI operations, systems implementing one or more language models-such as one or more large language models (LLMs), cloud computing and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more large language models (LLMs), one or more vision language models (VLMs), and/or one or more multimodal language models, systems for performing light transport simulation, systems for performing collaborative content creation for 3D assets, systems implemented at least partially using cloud computing resources, and/or other types of systems.

### Example Autonomous Vehicle

FIG. 9A is an illustration of an example autonomous vehicle 900, in accordance with some embodiments of the present disclosure. The autonomous vehicle 900 (alternatively referred to herein as the “vehicle 900”) may include, without limitation, a passenger vehicle, such as a car, a truck, a bus, a first responder vehicle, a shuttle, an electric or motorized bicycle, a motorcycle, a fire truck, a police vehicle, an ambulance, a boat, a construction vehicle, an underwater craft, a robotic vehicle, a drone, an airplane, a vehicle coupled to a trailer (e.g., a semi-tractor-trailer truck used for hauling cargo), and/or another type of vehicle (e.g., that is unmanned and/or that accommodates one or more passengers). Autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The vehicle 900 may be capable of functionality in accordance with one or more of Level 3-Level 5 of the autonomous driving levels. The vehicle 900 may be capable of functionality in accordance with one or more of Level 1-Level 5 of the autonomous driving levels. For example, the vehicle 900 may be capable of driver assistance (Level 1), partial automation (Level 2), conditional automation (Level 3), high automation (Level 4), and/or full automation (Level 5), depending on the embodiment. The term “autonomous,” as used herein, may include any and/or all types of autonomy for the vehicle 900 or other machine, such as being fully autonomous, being highly autonomous, being conditionally autonomous, being partially autonomous, providing assistive autonomy, being semi-autonomous, being primarily autonomous, or other designation.

The vehicle 900 may include components such as a chassis, a vehicle body, wheels (e.g., 2, 4, 6, 8, 18, etc.), tires, axles, and other components of a vehicle. The vehicle 900 may include a propulsion system 950, such as an internal combustion engine, hybrid electric power plant, an all-electric engine, and/or another propulsion system type. The propulsion system 950 may be connected to a drive train of the vehicle 900, which may include a transmission, to enable the propulsion of the vehicle 900. The propulsion system 950 may be controlled in response to receiving signals from the throttle/accelerator 952.

A steering system 954, which may include a steering wheel, may be used to steer the vehicle 900 (e.g., along a desired path or route) when the propulsion system 950 is operating (e.g., when the vehicle is in motion). The steering system 954 may receive signals from a steering actuator 956. The steering wheel may be optional for full automation (Level 5) functionality.

The brake sensor system 946 may be used to operate the vehicle brakes in response to receiving signals from the brake actuators 948 and/or brake sensors.

Controller(s) 936, which may include one or more system on chips (SoCs) 904 (FIG. 9C) and/or GPU(s), may provide signals (e.g., representative of commands) to one or more components and/or systems of the vehicle 900. For example, the controller(s) may send signals to operate the vehicle brakes via one or more brake actuators 948, to operate the steering system 954 via one or more steering actuators 956, to operate the propulsion system 950 via one or more throttle/accelerators 952. The controller(s) 936 may include one or more onboard (e.g., integrated) computing devices (e.g., supercomputers) that process sensor signals, and output operation commands (e.g., signals representing commands) to enable autonomous driving and/or to assist a human driver in driving the vehicle 900. The controller(s) 936 may include a first controller 936 for autonomous driving functions, a second controller 936 for functional safety functions, a third controller 936 for artificial intelligence functionality (e.g., computer vision), a fourth controller 936 for infotainment functionality, a fifth controller 936 for redundancy in emergency conditions, and/or other controllers. In some examples, a single controller 936 may handle two or more of the above functionalities, two or more controllers 936 may handle a single functionality, and/or any combination thereof.

The controller(s) 936 may provide the signals for controlling one or more components and/or systems of the vehicle 900 in response to sensor data received from one or more sensors (e.g., sensor inputs). The sensor data may be received from, for example and without limitation, global navigation satellite systems (“GNSS”) sensor(s) 958 (e.g., Global Positioning System sensor(s)), RADAR sensor(s) 960, ultrasonic sensor(s) 962, LIDAR sensor(s) 964, inertial measurement unit (IMU) sensor(s) 966 (e.g., accelerometer(s), gyroscope(s), magnetic compass(es), magnetometer(s), etc.), microphone(s) 996, stereo camera(s) 968, wide-view camera(s) 970 (e.g., fisheye cameras), infrared camera(s) 972, surround camera(s) 974 (e.g., 360 degree cameras), long-range and/or mid-range camera(s) 998, speed sensor(s) 944 (e.g., for measuring the speed of the vehicle 900), vibration sensor(s) 942, steering sensor(s) 940, brake sensor(s) (e.g., as part of the brake sensor system 946), and/or other sensor types.

One or more of the controller(s) 936 may receive inputs (e.g., represented by input data) from an instrument cluster 932 of the vehicle 900 and provide outputs (e.g., represented by output data, display data, etc.) via a human-machine interface (HMI) display 934, an audible annunciator, a loudspeaker, and/or via other components of the vehicle 900. The outputs may include information such as vehicle velocity, speed, time, map data (e.g., the High Definition (“HD”) map 922 of FIG. 9C), location data (e.g., the vehicle's 900 location, such as on a map), direction, location of other vehicles (e.g., an occupancy grid), information about objects and status of objects as perceived by the controller(s) 936, etc. For example, the HMI display 934 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The vehicle 900 further includes a network interface 924 which may use one or more wireless antenna(s) 926 and/or modem(s) to communicate over one or more networks. For example, the network interface 924 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”), etc. The wireless antenna(s) 926 may also enable communication between objects in the environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc.

FIG. 9B is an example of camera locations and fields of view for the example autonomous vehicle 900 of FIG. 9A, in accordance with some embodiments of the present disclosure. The cameras and respective fields of view are one example embodiment and are not intended to be limiting. For example, additional and/or alternative cameras may be included and/or the cameras may be located at different locations on the vehicle 900.

The camera types for the cameras may include, but are not limited to, digital cameras that may be adapted for use with the components and/or systems of the vehicle 900. The camera(s) may operate at automotive safety integrity level (ASIL) B and/or at another ASIL. The camera types may be capable of any image capture rate, such as 60 frames per second (fps), 120 fps, 240 fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

In some examples, one or more of the camera(s) may be used to perform advanced driver assistance systems (ADAS) functions (e.g., as part of a redundant or fail-safe design). For example, a Multi-Function Mono Camera may be installed to provide functions including lane departure warning, traffic sign assist and intelligent headlamp control. One or more of the camera(s) (e.g., all of the cameras) may record and provide image data (e.g., video) simultaneously.

One or more of the cameras may be mounted in a mounting assembly, such as a custom designed (three dimensional (“3D”) printed) assembly, in order to cut out stray light and reflections from within the car (e.g., reflections from the dashboard reflected in the windshield mirrors) which may interfere with the camera's image data capture abilities. With reference to wing-mirror mounting assemblies, the wing-mirror assemblies may be custom 3D printed so that the camera mounting plate matches the shape of the wing-mirror. In some examples, the camera(s) may be integrated into the wing-mirror. For side-view cameras, the camera(s) may also be integrated within the four pillars at each corner of the cabin.

Cameras with a field of view that include portions of the environment in front of the vehicle 900 (e.g., front-facing cameras) may be used for surround view, to help identify forward facing paths and obstacles, as well aid in, with the help of one or more controllers 936 and/or control SoCs, providing information critical to generating an occupancy grid and/or determining the preferred vehicle paths. Front-facing cameras may be used to perform many of the same ADAS functions as LIDAR, including emergency braking, pedestrian detection, and collision avoidance. Front-facing cameras may also be used for ADAS functions and systems including Lane Departure Warnings (“LDW”), Autonomous Cruise Control (“ACC”), and/or other functions such as traffic sign recognition.

A variety of cameras may be used in a front-facing configuration, including, for example, a monocular camera platform that includes a complementary metal oxide semiconductor (“CMOS”) color imager. Another example may be a wide-view camera(s) 970 that may be used to perceive objects coming into view from the periphery (e.g., pedestrians, crossing traffic or bicycles). Although only one wide-view camera is illustrated in FIG. 9B, there may be any number (including zero) of wide-view cameras 970 on the vehicle 900. In addition, any number of long-range camera(s) 998 (e.g., a long-view stereo camera pair) may be used for depth-based object detection, especially for objects for which a neural network has not yet been trained. The long-range camera(s) 998 may also be used for object detection and classification, as well as basic object tracking.

Any number of stereo cameras 968 may also be included in a front-facing configuration. In at least one embodiment, one or more of stereo camera(s) 968 may include an integrated control unit comprising a scalable processing unit, which may provide a programmable logic (“FPGA”) and a multi-core micro-processor with an integrated Controller Area Network (“CAN”) or Ethernet interface on a single chip. Such a unit may be used to generate a 3D map of the vehicle's environment, including a distance estimate for all the points in the image. An alternative stereo camera(s) 968 may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 968 may be used in addition to, or alternatively from, those described herein.

Cameras with a field of view that include portions of the environment to the side of the vehicle 900 (e.g., side-view cameras) may be used for surround view, providing information used to create and update the occupancy grid, as well as to generate side impact collision warnings. For example, surround camera(s) 974 (e.g., four surround cameras 974 as illustrated in FIG. 9B) may be positioned to on the vehicle 900. The surround camera(s) 974 may include wide-view camera(s) 970, fisheye camera(s), 360 degree camera(s), and/or the like. Four example, four fisheye cameras may be positioned on the vehicle's front, rear, and sides. In an alternative arrangement, the vehicle may use three surround camera(s) 974 (e.g., left, right, and rear), and may leverage one or more other camera(s) (e.g., a forward-facing camera) as a fourth surround view camera.

Cameras with a field of view that include portions of the environment to the rear of the vehicle 900 (e.g., rear-view cameras) may be used for park assistance, surround view, rear collision warnings, and creating and updating the occupancy grid. A wide variety of cameras may be used including, but not limited to, cameras that are also suitable as a front-facing camera(s) (e.g., long-range and/or mid-range camera(s) 998, stereo camera(s) 968), infrared camera(s) 972, etc.), as described herein.

FIG. 9C is a block diagram of an example system architecture for the example autonomous vehicle 900 of FIG. 9A, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

Each of the components, features, and systems of the vehicle 900 in FIG. 9C are illustrated as being connected via bus 902. The bus 902 may include a Controller Area Network (CAN) data interface (alternatively referred to herein as a “CAN bus”). A CAN may be a network inside the vehicle 900 used to aid in control of various features and functionality of the vehicle 900, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant.

Although the bus 902 is described herein as being a CAN bus, this is not intended to be limiting. For example, in addition to, or alternatively from, the CAN bus, FlexRay and/or Ethernet may be used. Additionally, although a single line is used to represent the bus 902, this is not intended to be limiting. For example, there may be any number of busses 902, which may include one or more CAN busses, one or more FlexRay busses, one or more Ethernet busses, and/or one or more other types of busses using a different protocol. In some examples, two or more busses 902 may be used to perform different functions, and/or may be used for redundancy. For example, a first bus 902 may be used for collision avoidance functionality and a second bus 902 may be used for actuation control. In any example, each bus 902 may communicate with any of the components of the vehicle 900, and two or more busses 902 may communicate with the same components. In some examples, each SoC 904, each controller 936, and/or each computer within the vehicle may have access to the same input data (e.g., inputs from sensors of the vehicle 900), and may be connected to a common bus, such the CAN bus.

The vehicle 900 may include one or more controller(s) 936, such as those described herein with respect to FIG. 9A. The controller(s) 936 may be used for a variety of functions. The controller(s) 936 may be coupled to any of the various other components and systems of the vehicle 900, and may be used for control of the vehicle 900, artificial intelligence of the vehicle 900, infotainment for the vehicle 900, and/or the like.

The vehicle 900 may include a system(s) on a chip (SoC) 904. The SoC 904 may include CPU(s) 906, GPU(s) 908, processor(s) 910, cache(s) 912, accelerator(s) 914, data store(s) 916, and/or other components and features not illustrated. The SoC(s) 904 may be used to control the vehicle 900 in a variety of platforms and systems. For example, the SoC(s) 904 may be combined in a system (e.g., the system of the vehicle 900) with an HD map 922 which may obtain map refreshes and/or updates via a network interface 924 from one or more servers (e.g., server(s) 978 of FIG. 9D).

The CPU(s) 906 may include a CPU cluster or CPU complex (alternatively referred to herein as a “CCPLEX”). The CPU(s) 906 may include multiple cores and/or L2 caches. For example, in some embodiments, the CPU(s) 906 may include eight cores in a coherent multi-processor configuration. In some embodiments, the CPU(s) 906 may include four dual-core clusters where each cluster has a dedicated L2 cache (e.g., a 2 MB L2 cache). The CPU(s) 906 (e.g., the CCPLEX) may be configured to support simultaneous cluster operation enabling any combination of the clusters of the CPU(s) 906 to be active at any given time.

The CPU(s) 906 may implement power management capabilities that include one or more of the following features: individual hardware blocks may be clock-gated automatically when idle to save dynamic power; each core clock may be gated when the core is not actively executing instructions due to execution of WFI/WFE instructions; each core may be independently power-gated; each core cluster may be independently clock-gated when all cores are clock-gated or power-gated; and/or each core cluster may be independently power-gated when all cores are power-gated. The CPU(s) 906 may further implement an enhanced algorithm for managing power states, where allowed power states and expected wakeup times are specified, and the hardware/microcode determines the best power state to enter for the core, cluster, and CCPLEX. The processing cores may support simplified power state entry sequences in software with the work offloaded to microcode.

The GPU(s) 908 may include an integrated GPU (alternatively referred to herein as an “iGPU”). The GPU(s) 908 may be programmable and may be efficient for parallel workloads. The GPU(s) 908, in some examples, may use an enhanced tensor instruction set. The GPU(s) 908 may include one or more streaming microprocessors, where each streaming microprocessor may include an L1 cache (e.g., an L1 cache with at least 96 KB storage capacity), and two or more of the streaming microprocessors may share an L2 cache (e.g., an L2 cache with a 512 KB storage capacity). In some embodiments, the GPU(s) 908 may include at least eight streaming microprocessors. The GPU(s) 908 may use compute application programming interface(s) (API(s)). In addition, the GPU(s) 908 may use one or more parallel computing platforms and/or programming models (e.g., NVIDIA's CUDA).

The GPU(s) 908 may be power-optimized for best performance in automotive and embedded use cases. For example, the GPU(s) 908 may be fabricated on a Fin field-effect transistor (FinFET). However, this is not intended to be limiting and the GPU(s) 908 may be fabricated using other semiconductor manufacturing processes. Each streaming microprocessor may incorporate a number of mixed-precision processing cores partitioned into multiple blocks. For example, and without limitation, 64 PF32 cores and 32 PF64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an L0 instruction cache, a warp scheduler, a dispatch unit, and/or a 64 KB register file. In addition, the streaming microprocessors may include independent parallel integer and floating-point data paths to provide for efficient execution of workloads with a mix of computation and addressing calculations. The streaming microprocessors may include independent thread scheduling capability to enable finer-grain synchronization and cooperation between parallel threads. The streaming microprocessors may include a combined L1 data cache and shared memory unit in order to improve performance while simplifying programming.

The GPU(s) 908 may include a high bandwidth memory (HBM) and/or a 16 GB HBM2 memory subsystem to provide, in some examples, about 900 GB/second peak memory bandwidth. In some examples, in addition to, or alternatively from, the HBM memory, a synchronous graphics random-access memory (SGRAM) may be used, such as a graphics double data rate type five synchronous random-access memory (GDDR5).

The GPU(s) 908 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 908 to access the CPU(s) 906 page tables directly. In such examples, when the GPU(s) 908 memory management unit (MMU) experiences a miss, an address translation request may be transmitted to the CPU(s) 906. In response, the CPU(s) 906 may look in its page tables for the virtual-to-physical mapping for the address and transmits the translation back to the GPU(s) 908. As such, unified memory technology may allow a single unified virtual address space for memory of both the CPU(s) 906 and the GPU(s) 908, thereby simplifying the GPU(s) 908 programming and porting of applications to the GPU(s) 908.

In addition, the GPU(s) 908 may include an access counter that may keep track of the frequency of access of the GPU(s) 908 to memory of other processors. The access counter may help ensure that memory pages are moved to the physical memory of the processor that is accessing the pages most frequently.

The SoC(s) 904 may include any number of cache(s) 912, including those described herein. For example, the cache(s) 912 may include an L3 cache that is available to both the CPU(s) 906 and the GPU(s) 908 (e.g., that is connected both the CPU(s) 906 and the GPU(s) 908). The cache(s) 912 may include a write-back cache that may keep track of states of lines, such as by using a cache coherence protocol (e.g., MEI, MESI, MSI, etc.). The L3 cache may include 4 MB or more, depending on the embodiment, although smaller cache sizes may be used.

The SoC(s) 904 may include an arithmetic logic unit(s) (ALU(s)) which may be leveraged in performing processing with respect to any of the variety of tasks or operations of the vehicle 900—such as processing DNNs. In addition, the SoC(s) 904 may include a floating point unit(s) (FPU(s))—or other math coprocessor or numeric coprocessor types—for performing mathematical operations within the system. For example, the SoC(s) 904 may include one or more FPUs integrated as execution units within a CPU(s) 906 and/or GPU(s) 908.

The SoC(s) 904 may include one or more accelerators 914 (e.g., hardware accelerators, software accelerators, or a combination thereof). For example, the SoC(s) 904 may include a hardware acceleration cluster that may include optimized hardware accelerators and/or large on-chip memory. The large on-chip memory (e.g., 4 MB of SRAM), may enable the hardware acceleration cluster to accelerate neural networks and other calculations. The hardware acceleration cluster may be used to complement the GPU(s) 908 and to off-load some of the tasks of the GPU(s) 908 (e.g., to free up more cycles of the GPU(s) 908 for performing other tasks). As an example, the accelerator(s) 914 may be used for targeted workloads (e.g., perception, convolutional neural networks (CNNs), etc.) that are stable enough to be amenable to acceleration. The term “CNN,” as used herein, may include all types of CNNs, including region-based or regional convolutional neural networks (RCNNs) and Fast RCNNs (e.g., as used for object detection).

The accelerator(s) 914 (e.g., the hardware acceleration cluster) may include a deep learning accelerator(s) (DLA). The DLA(s) may include one or more Tensor processing units (TPUs) that may be configured to provide an additional ten trillion operations per second for deep learning applications and inferencing. The TPUs may be accelerators configured to, and optimized for, performing image processing functions (e.g., for CNNs, RCNNs, etc.). The DLA(s) may further be optimized for a specific set of neural network types and floating point operations, as well as inferencing. The design of the DLA(s) may provide more performance per millimeter than a general-purpose GPU, and vastly exceeds the performance of a CPU. The TPU(s) may perform several functions, including a single-instance convolution function, supporting, for example, INT8, INT16, and FP16 data types for both features and weights, as well as post-processor functions.

The DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events. The DLA(s) may also execute one or more neural networks included in generative world model 242 and/or other machine learning models involved in perception, navigation, and/or other tasks.

The DLA(s) may perform any function of the GPU(s) 908, and by using an inference accelerator, for example, a designer may target either the DLA(s) or the GPU(s) 908 for any function. For example, the designer may focus processing of CNNs and floating point operations on the DLA(s) and leave other functions to the GPU(s) 908 and/or other accelerator(s) 914.

The accelerator(s) 914 (e.g., the hardware acceleration cluster) may include a programmable vision accelerator(s) (PVA), which may alternatively be referred to herein as a computer vision accelerator. The PVA(s) may be designed and configured to accelerate computer vision algorithms for the advanced driver assistance systems (ADAS), autonomous driving, and/or augmented reality (AR) and/or virtual reality (VR) applications. The PVA(s) may provide a balance between performance and flexibility. For example, each PVA(s) may include, for example and without limitation, any number of reduced instruction set computer (RISC) cores, direct memory access (DMA), and/or any number of vector processors.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA may enable components of the PVA(s) to access the system memory independently of the CPU(s) 906. The DMA may support any number of features used to provide optimization to the PVA including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors may be programmable processors that may be designed to efficiently and flexibly execute programming for computer vision algorithms and provide signal processing capabilities. In some examples, the PVA may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA, and may include a vector processing unit (VPU), an instruction cache, and/or vector memory (e.g., VMEM). A VPU core may include a digital signal processor such as, for example, a single instruction, multiple data (SIMD), very long instruction word (VLIW) digital signal processor. The combination of the SIMD and VLIW may enhance throughput and speed.

Each of the vector processors may include an instruction cache and may be coupled to dedicated memory. As a result, in some examples, each of the vector processors may be configured to execute independently of the other vector processors. In other examples, the vector processors that are included in a particular PVA may be configured to employ data parallelism. For example, in some embodiments, the plurality of vector processors included in a single PVA may execute the same computer vision algorithm, but on different regions of an image. In other examples, the vector processors included in a particular PVA may simultaneously execute different computer vision algorithms, on the same image, or even execute different algorithms on sequential images or portions of an image. Among other things, any number of PVAs may be included in the hardware acceleration cluster and any number of vector processors may be included in each of the PVAs. In addition, the PVA(s) may include additional error correcting code (ECC) memory, to enhance overall system safety.

The accelerator(s) 914 (e.g., the hardware acceleration cluster) may include a computer vision network on-chip and SRAM, for providing a high-bandwidth, low latency SRAM for the accelerator(s) 914. In some examples, the on-chip memory may include at least 4 MB SRAM, consisting of, for example and without limitation, eight field-configurable memory blocks, that may be accessible by both the PVA and the DLA. Each pair of memory blocks may include an advanced peripheral bus (APB) interface, configuration circuitry, a controller, and a multiplexer. Any type of memory may be used. The PVA and DLA may access the memory via a backbone that provides the PVA and DLA with high-speed access to memory. The backbone may include a computer vision network on-chip that interconnects the PVA and the DLA to the memory (e.g., using the APB).

The computer vision network on-chip may include an interface that determines, before transmission of any control signal/address/data, that both the PVA and the DLA provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

In some examples, the SoC(s) 904 may include a real-time ray-tracing hardware accelerator, such as described in U.S. patent application Ser. No. 16/101,232, filed on Aug. 10, 2018. The real-time ray-tracing hardware accelerator may be used to quickly and efficiently determine the positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses. In some embodiments, one or more tree traversal units (TTUs) may be used for executing one or more ray-tracing related operations.

The accelerator(s) 914 (e.g., the hardware accelerator cluster) have a wide array of uses for autonomous driving. The PVA may be a programmable vision accelerator that may be used for key processing stages in ADAS and autonomous vehicles. The PVA's capabilities are a good match for algorithmic domains needing predictable processing, at low power and low latency. In other words, the PVA performs well on semi-dense or dense regular computation, even on small data sets, which need predictable run-times with low latency and low power. Thus, in the context of platforms for autonomous vehicles, the PVAs are designed to run classic computer vision algorithms, as they are efficient at object detection and operating on integer math.

For example, according to one embodiment of the technology, the PVA is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA may perform computer stereo vision function on inputs from two monocular cameras.

In some examples, the PVA may be used to perform dense optical flow. According to process raw RADAR data (e.g., using a 4D Fast Fourier Transform) to provide Processed RADAR. In other examples, the PVA is used for time of flight depth processing, by processing raw time of flight data to provide processed time of flight data, for example.

The DLA may be used to run any type of network to enhance control and driving safety, including for example, a neural network that outputs a measure of confidence for each object detection. Such a confidence value may be interpreted as a probability, or as providing a relative “weight” of each detection compared to other detections. This confidence value enables the system to make further decisions regarding which detections should be considered as true positive detections rather than false positive detections. For example, the system may set a threshold value for the confidence and consider only the detections exceeding the threshold value as true positive detections. In an automatic emergency braking (AEB) system, false positive detections would cause the vehicle to automatically perform emergency braking, which is obviously undesirable. Therefore, only the most confident detections should be considered as triggers for AEB. The DLA may run a neural network for regressing the confidence value. The neural network may take as its input at least some subset of parameters, such as bounding shape dimensions, ground plane estimate obtained (e.g. from another subsystem), IMU sensor 966 output that correlates with the vehicle 900 orientation, distance, 3D location estimates of the object obtained from the neural network and/or other sensors (e.g., LIDAR sensor(s) 964 or RADAR sensor(s) 960), among others.

The SoC(s) 904 may include data store(s) 916 (e.g., memory). The data store(s) 916 may be on-chip memory of the SoC(s) 904, which may store neural networks to be executed on the GPU and/or the DLA. In some examples, the data store(s) 916 may be large enough in capacity to store multiple instances of neural networks (e.g., neural networks included in generative world model 242) for redundancy and safety. The data store(s) 912 may comprise L2 or L3 cache(s) 912. Reference to the data store(s) 916 may include reference to the memory associated with the PVA, DLA, and/or other accelerator(s) 914, as described herein.

The SoC(s) 904 may include one or more processor(s) 910 (e.g., embedded processors). The processor(s) 910 may include a boot and power management processor that may be a dedicated processor and subsystem to handle boot power and management functions and related security enforcement. The boot and power management processor may be a part of the SoC(s) 904 boot sequence and may provide runtime power management services. The boot power and management processor may provide clock and voltage programming, assistance in system low power state transitions, management of SoC(s) 904 thermals and temperature sensors, and/or management of the SoC(s) 904 power states. Each temperature sensor may be implemented as a ring-oscillator whose output frequency is proportional to temperature, and the SoC(s) 904 may use the ring-oscillators to detect temperatures of the CPU(s) 906, GPU(s) 908, and/or accelerator(s) 914. If temperatures are determined to exceed a threshold, the boot and power management processor may enter a temperature fault routine and put the SoC(s) 904 into a lower power state and/or put the vehicle 900 into a chauffeur to safe stop mode (e.g., bring the vehicle 900 to a safe stop).

The processor(s) 910 may further include a set of embedded processors that may serve as an audio processing engine. The audio processing engine may be an audio subsystem that enables full hardware support for multi-channel audio over multiple interfaces, and a broad and flexible range of audio I/O interfaces. In some examples, the audio processing engine is a dedicated processor core with a digital signal processor with dedicated RAM.

The processor(s) 910 may further include an always on processor engine that may provide necessary hardware features to support low power sensor management and wake use cases. The always on processor engine may include a processor core, a tightly coupled RAM, supporting peripherals (e.g., timers and interrupt controllers), various I/O controller peripherals, and routing logic.

The processor(s) 910 may further include a safety cluster engine that includes a dedicated processor subsystem to handle safety management for automotive applications. The safety cluster engine may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations.

The processor(s) 910 may further include a real-time camera engine that may include a dedicated processor subsystem for handling real-time camera management; a high-dynamic range signal processor that may include an image signal processor that is a hardware engine that is part of the camera processing pipeline; and/or a video image compositor that may be a processing block (e.g., implemented on a microprocessor) that implements video post-processing functions needed by a video playback application to produce the final image for the player window. The video image compositor may perform lens distortion correction on wide-view camera(s) 970, surround camera(s) 974, and/or on in-cabin monitoring camera sensors. In-cabin monitoring camera sensor is preferably monitored by a neural network running on another instance of the Advanced SoC, configured to identify in cabin events and respond accordingly. An in-cabin system may perform lip reading to activate cellular service and place a phone call, dictate emails, change the vehicle's destination, activate or change the vehicle's infotainment system and settings, or provide voice-activated web surfing. Certain functions are available to the driver only when the vehicle is operating in an autonomous mode, and are disabled otherwise.

The video image compositor may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

The video image compositor may also be configured to perform stereo rectification on input stereo lens frames. The video image compositor may further be used for user interface composition when the operating system desktop is in use, and the GPU(s) 908 is not required to continuously render new surfaces. Even when the GPU(s) 908 is powered on and active doing 3D rendering, the video image compositor may be used to offload the GPU(s) 908 to improve performance and responsiveness.

The SoC(s) 904 may further include a mobile industry processor interface (MIPI) camera serial interface for receiving video and input from cameras, a high-speed interface, and/or a video input block that may be used for camera and related pixel input functions. The SoC(s) 904 may further include an input/output controller(s) that may be controlled by software and may be used for receiving I/O signals that are uncommitted to a specific role.

The SoC(s) 904 may further include a broad range of peripheral interfaces to enable communication with peripherals, audio codecs, power management, and/or other devices. The SoC(s) 904 may be used to process data from cameras (e.g., connected over Gigabit Multimedia Serial Link and Ethernet), sensors (e.g., LIDAR sensor(s) 964, RADAR sensor(s) 960, etc. that may be connected over Ethernet), data from bus 902 (e.g., speed of vehicle 900, steering wheel position, etc.), data from GNSS sensor(s) 958 (e.g., connected over Ethernet or CAN bus). The SoC(s) 904 may further include dedicated high-performance mass storage controllers that may include their own DMA engines, and that may be used to free the CPU(s) 906 from routine data management tasks.

The SoC(s) 904 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. The SoC(s) 904 may be faster, more reliable, and even more energy-efficient and space-efficient than conventional systems. For example, the accelerator(s) 914, when combined with the CPU(s) 906, the GPU(s) 908, and the data store(s) 916, may provide for a fast, efficient platform for level 3-5 autonomous vehicles.

The technology thus provides capabilities and functionality that cannot be achieved by conventional systems. For example, computer vision algorithms may be executed on CPUs, which may be configured using high-level programming language, such as the C programming language, to execute a wide variety of processing algorithms across a wide variety of visual data. However, CPUs are oftentimes unable to meet the performance requirements of many computer vision applications, such as those related to execution time and power consumption, for example. In particular, many CPUs are unable to execute complex object detection algorithms in real-time, which is a requirement of in-vehicle ADAS applications, and a requirement for practical Level 3-5 autonomous vehicles.

In contrast to conventional systems, by providing a CPU complex, GPU complex, and a hardware acceleration cluster, the technology described herein allows for multiple neural networks (e.g., neural networks in generative world model 242) to be performed simultaneously and/or sequentially, and for the results to be combined together to enable Level 3-5 autonomous driving functionality. For example, a CNN executing on the DLA or dGPU (e.g., the GPU(s) 920) may include a text and word recognition, allowing the supercomputer to read and understand traffic signs, including signs for which the neural network has not been specifically trained. The DLA may further include a neural network that is able to identify, interpret, and provides semantic understanding of the sign, and to pass that semantic understanding to the path planning modules running on the CPU Complex.

As another example, multiple neural networks may be run simultaneously, as is required for Level 3, 4, or 5 driving. For example, a warning sign consisting of “Caution: flashing lights indicate icy conditions,” along with an electric light, may be independently or collectively interpreted by several neural networks. The sign itself may be identified as a traffic sign by a first deployed neural network (e.g., a neural network that has been trained), the text “Flashing lights indicate icy conditions” may be interpreted by a second deployed neural network, which informs the vehicle's path planning software (preferably executing on the CPU Complex) that when flashing lights are detected, icy conditions exist. The flashing light may be identified by operating a third deployed neural network over multiple frames, informing the vehicle's path-planning software of the presence (or absence) of flashing lights. All three neural networks may run simultaneously, such as within the DLA and/or on the GPU(s) 908.

In some examples, a CNN for facial recognition and vehicle owner identification may use data from camera sensors to identify the presence of an authorized driver and/or owner of the vehicle 900. The always on sensor processing engine may be used to unlock the vehicle when the owner approaches the driver door and turn on the lights, and, in security mode, to disable the vehicle when the owner leaves the vehicle. In this way, the SoC(s) 904 provide for security against theft and/or carjacking.

In another example, a CNN for emergency vehicle detection and identification may use data from microphones 996 to detect and identify emergency vehicle sirens. In contrast to conventional systems, that use general classifiers to detect sirens and manually extract features, the SoC(s) 904 use the CNN for classifying environmental and urban sounds, as well as classifying visual data. In a preferred embodiment, the CNN running on the DLA is trained to identify the relative closing speed of the emergency vehicle (e.g., by using the Doppler Effect). The CNN may also be trained to identify emergency vehicles specific to the local area in which the vehicle is operating, as identified by GNSS sensor(s) 958. Thus, for example, when operating in Europe the CNN will seek to detect European sirens, and when in the United States the CNN will seek to identify only North American sirens. Once an emergency vehicle is detected, a control program may be used to execute an emergency vehicle safety routine, slowing the vehicle, pulling over to the side of the road, parking the vehicle, and/or idling the vehicle, with the assistance of ultrasonic sensors 962, until the emergency vehicle(s) passes.

The vehicle may include a CPU(s) 918 (e.g., discrete CPU(s), or dCPU(s)), that may be coupled to the SoC(s) 904 via a high-speed interconnect (e.g., PCIe). The CPU(s) 918 may include an X86 processor, for example. The CPU(s) 918 may be used to perform any of a variety of functions, including arbitrating potentially inconsistent results between ADAS sensors and the SoC(s) 904, and/or monitoring the status and health of the controller(s) 936 and/or infotainment SoC 930, for example.

The vehicle 900 may include a GPU(s) 920 (e.g., discrete GPU(s), or dGPU(s)), that may be coupled to the SoC(s) 904 via a high-speed interconnect (e.g., NVIDIA's NVLINK). The GPU(s) 920 may provide additional artificial intelligence functionality, such as by executing redundant and/or different neural networks, and may be used to train and/or update neural networks based on input (e.g., sensor data) from sensors of the vehicle 900.

The vehicle 900 may further include the network interface 924 which may include one or more wireless antennas 926 (e.g., one or more wireless antennas for different communication protocols, such as a cellular antenna, a Bluetooth antenna, etc.). The network interface 924 may be used to enable wireless connectivity over the Internet with the cloud (e.g., with the server(s) 978 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the vehicle 900 information about vehicles in proximity to the vehicle 900 (e.g., vehicles in front of, on the side of, and/or behind the vehicle 900). This functionality may be part of a cooperative adaptive cruise control functionality of the vehicle 900.

The network interface 924 may include a SoC that provides modulation and demodulation functionality and enables the controller(s) 936 to communicate over wireless networks. The network interface 924 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. The network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

The vehicle 900 may further include data store(s) 928 which may include off-chip (e.g., off the SoC(s) 904) storage. The data store(s) 928 may include one or more storage elements including RAM, SRAM, DRAM, VRAM, Flash, hard disks, and/or other components and/or devices that may store at least one bit of data.

The vehicle 900 may further include GNSS sensor(s) 958. The GNSS sensor(s) 958 (e.g., GPS, assisted GPS sensors, differential GPS (DGPS) sensors, etc.), to assist in mapping, perception, occupancy grid generation, and/or path planning functions. Any number of GNSS sensor(s) 958 may be used, including, for example and without limitation, a GPS using a USB connector with an Ethernet to Serial (RS-232) bridge.

The vehicle 900 may further include RADAR sensor(s) 960. The RADAR sensor(s) 960 may be used by the vehicle 900 for long-range vehicle detection, even in darkness and/or severe weather conditions. RADAR functional safety levels may be ASIL B. The RADAR sensor(s) 960 may use the CAN and/or the bus 902 (e.g., to transmit data generated by the RADAR sensor(s) 960) for control and to access object tracking data, with access to Ethernet to access raw data in some examples. A wide variety of RADAR sensor types may be used. For example, and without limitation, the RADAR sensor(s) 960 may be suitable for front, rear, and side RADAR use. In some example, Pulse Doppler RADAR sensor(s) are used.

The RADAR sensor(s) 960 may include different configurations, such as long range with narrow field of view, short range with wide field of view, short range side coverage, etc. In some examples, long-range RADAR may be used for adaptive cruise control functionality. The long-range RADAR systems may provide a broad field of view realized by two or more independent scans, such as within a 250 m range. The RADAR sensor(s) 960 may help in distinguishing between static and moving objects, and may be used by ADAS systems for emergency brake assist and forward collision warning. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the vehicle's 900 surroundings at higher speeds with minimal interference from traffic in adjacent lanes. The other two antennae may expand the field of view, making it possible to quickly detect vehicles entering or leaving the vehicle's 900 lane.

Mid-range RADAR systems may include, as an example, a range of up to 960 m (front) or 80 m (rear), and a field of view of up to 42 degrees (front) or 950 degrees (rear). Short-range RADAR systems may include, without limitation, RADAR sensors designed to be installed at both ends of the rear bumper. When installed at both ends of the rear bumper, such a RADAR sensor systems may create two beams that constantly monitor the blind spot in the rear and next to the vehicle.

Short-range RADAR systems may be used in an ADAS system for blind spot detection and/or lane change assist.

The vehicle 900 may further include ultrasonic sensor(s) 962. The ultrasonic sensor(s) 962, which may be positioned at the front, back, and/or the sides of the vehicle 900, may be used for park assist and/or to create and update an occupancy grid. A wide variety of ultrasonic sensor(s) 962 may be used, and different ultrasonic sensor(s) 962 may be used for different ranges of detection (e.g., 2.5 m, 4 m). The ultrasonic sensor(s) 962 may operate at functional safety levels of ASIL B.

The vehicle 900 may include LIDAR sensor(s) 964. The LIDAR sensor(s) 964 may be used for object and pedestrian detection, emergency braking, collision avoidance, and/or other functions. The LIDAR sensor(s) 964 may be functional safety level ASIL B. In some examples, the vehicle 900 may include multiple LIDAR sensors 964 (e.g., two, four, six, etc.) that may use Ethernet (e.g., to provide data to a Gigabit Ethernet switch).

In some examples, the LIDAR sensor(s) 964 may be capable of providing a list of objects and their distances for a 360-degree field of view. Commercially available LIDAR sensor(s) 964 may have an advertised range of approximately 900 m, with an accuracy of 2 cm-3 cm, and with support for a 900 Mbps Ethernet connection, for example. In some examples, one or more non-protruding LIDAR sensors 964 may be used. In such examples, the LIDAR sensor(s) 964 may be implemented as a small device that may be embedded into the front, rear, sides, and/or corners of the vehicle 900. The LIDAR sensor(s) 964, in such examples, may provide up to a 120-degree horizontal and 35-degree vertical field-of-view, with a 200 m range even for low-reflectivity objects. Front-mounted LIDAR sensor(s) 964 may be configured for a horizontal field of view between 45 degrees and 135 degrees.

In some examples, LIDAR technologies, such as 3D flash LIDAR, may also be used. 3D Flash LIDAR uses a flash of a laser as a transmission source, to illuminate vehicle surroundings up to approximately 200 m. A flash LIDAR unit includes a receptor, which records the laser pulse transit time and the reflected light on each pixel, which in turn corresponds to the range from the vehicle to the objects. Flash LIDAR may allow for highly accurate and distortion-free images of the surroundings to be generated with every laser flash. In some examples, four flash LIDAR sensors may be deployed, one at each side of the vehicle 900. Available 3D flash LIDAR systems include a solid-state 3D staring array LIDAR camera with no moving parts other than a fan (e.g., a non-scanning LIDAR device). The flash LIDAR device may use a 5 nanosecond class I (eye-safe) laser pulse per frame and may capture the reflected laser light in the form of 3D range point clouds and co-registered intensity data. By using flash LIDAR, and because flash LIDAR is a solid-state device with no moving parts, the LIDAR sensor(s) 964 may be less susceptible to motion blur, vibration, and/or shock.

The vehicle may further include IMU sensor(s) 966. The IMU sensor(s) 966 may be located at a center of the rear axle of the vehicle 900, in some examples. The IMU sensor(s) 966 may include, for example and without limitation, an accelerometer(s), a magnetometer(s), a gyroscope(s), a magnetic compass(es), and/or other sensor types. In some examples, such as in six-axis applications, the IMU sensor(s) 966 may include accelerometers and gyroscopes, while in nine-axis applications, the IMU sensor(s) 966 may include accelerometers, gyroscopes, and magnetometers.

In some embodiments, the IMU sensor(s) 966 may be implemented as a miniature, high performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 966 may enable the vehicle 900 to estimate heading without requiring input from a magnetic sensor by directly observing and correlating the changes in velocity from GPS to the IMU sensor(s) 966. In some examples, the IMU sensor(s) 966 and the GNSS sensor(s) 958 may be combined in a single integrated unit.

The vehicle may include microphone(s) 996 placed in and/or around the vehicle 900. The microphone(s) 996 may be used for emergency vehicle detection and identification, among other things.

The vehicle may further include any number of camera types, including stereo camera(s) 968, wide-view camera(s) 970, infrared camera(s) 972, surround camera(s) 974, long-range and/or mid-range camera(s) 998, and/or other camera types. The cameras may be used to capture image data around an entire periphery of the vehicle 900. The types of cameras used depends on the embodiments and requirements for the vehicle 900, and any combination of camera types may be used to provide the necessary coverage around the vehicle 900. In addition, the number of cameras may differ depending on the embodiment. For example, the vehicle may include six cameras, seven cameras, ten cameras, twelve cameras, and/or another number of cameras. The cameras may support, as an example and without limitation, Gigabit Multimedia Serial Link (GMSL) and/or Gigabit Ethernet. Each of the camera(s) is described with more detail herein with respect to FIG. 9A and FIG. 9B.

The vehicle 900 may further include vibration sensor(s) 942. The vibration sensor(s) 942 may measure vibrations of components of the vehicle, such as the axle(s). For example, changes in vibrations may indicate a change in road surfaces. In another example, when two or more vibration sensors 942 are used, the differences between the vibrations may be used to determine friction or slippage of the road surface (e.g., when the difference in vibration is between a power-driven axle and a freely rotating axle).

The vehicle 900 may include an ADAS system 938. The ADAS system 938 may include a SoC, in some examples. The ADAS system 938 may include autonomous/adaptive/automatic cruise control (ACC), cooperative adaptive cruise control (CACC), forward crash warning (FCW), automatic emergency braking (AEB), lane departure warnings (LDW), lane keep assist (LKA), blind spot warning (BSW), rear cross-traffic warning (RCTW), collision warning systems (CWS), lane centering (LC), and/or other features and functionality.

The ACC systems may use RADAR sensor(s) 960, LIDAR sensor(s) 964, and/or a camera(s). The ACC systems may include longitudinal ACC and/or lateral ACC. Longitudinal ACC monitors and controls the distance to the vehicle immediately ahead of the vehicle 900 and automatically adjust the vehicle speed to maintain a safe distance from vehicles ahead. Lateral ACC performs distance keeping, and advises the vehicle 900 to change lanes when necessary. Lateral ACC is related to other ADAS applications such as LCA and CWS.

CACC uses information from other vehicles that may be received via the network interface 924 and/or the wireless antenna(s) 926 from other vehicles via a wireless link, or indirectly, over a network connection (e.g., over the Internet). Direct links may be provided by a vehicle-to-vehicle (V2V) communication link, while indirect links may be infrastructure-to-vehicle (I2V) communication link. In general, the V2V communication concept provides information about the immediately preceding vehicles (e.g., vehicles immediately ahead of and in the same lane as the vehicle 900), while the 12V communication concept provides information about traffic further ahead. CACC systems may include either or both I2V and V2V information sources. Given the information of the vehicles ahead of the vehicle 900, CACC may be more reliable and it has potential to improve traffic flow smoothness and reduce congestion on the road.

FCW systems are designed to alert the driver to a hazard, so that the driver may take corrective action. FCW systems use a front-facing camera and/or RADAR sensor(s) 960, coupled to a dedicated processor, DSP, FPGA, and/or ASIC, that is electrically coupled to driver feedback, such as a display, speaker, and/or vibrating component. FCW systems may provide a warning, such as in the form of a sound, visual warning, vibration and/or a quick brake pulse.

AEB systems detect an impending forward collision with another vehicle or other object, and may automatically apply the brakes if the driver does not take corrective action within a specified time or distance parameter. AEB systems may use front-facing camera(s) and/or RADAR sensor(s) 960, coupled to a dedicated processor, DSP, FPGA, and/or ASIC. When the AEB system detects a hazard, it typically first alerts the driver to take corrective action to avoid the collision and, if the driver does not take corrective action, the AEB system may automatically apply the brakes in an effort to prevent, or at least mitigate, the impact of the predicted collision. AEB systems, may include techniques such as dynamic brake support and/or crash imminent braking.

LDW systems provide visual, audible, and/or tactile warnings, such as steering wheel or seat vibrations, to alert the driver when the vehicle 900 crosses lane markings. A LDW system does not activate when the driver indicates an intentional lane departure, by activating a turn signal. LDW systems may use front-side facing cameras, coupled to a dedicated processor, DSP, FPGA, and/or ASIC, that is electrically coupled to driver feedback, such as a display, speaker, and/or vibrating component.

LKA systems are a variation of LDW systems. LKA systems provide steering input or braking to correct the vehicle 900 if the vehicle 900 starts to exit the lane.

BSW systems detects and warn the driver of vehicles in an automobile's blind spot. BSW systems may provide a visual, audible, and/or tactile alert to indicate that merging or changing lanes is unsafe. The system may provide an additional warning when the driver uses a turn signal. BSW systems may use rear-side facing camera(s) and/or RADAR sensor(s) 960, coupled to a dedicated processor, DSP, FPGA, and/or ASIC, that is electrically coupled to driver feedback, such as a display, speaker, and/or vibrating component.

RCTW systems may provide visual, audible, and/or tactile notification when an object is detected outside the rear-camera range when the vehicle 900 is backing up. Some RCTW systems include AEB to ensure that the vehicle brakes are applied to avoid a crash. RCTW systems may use one or more rear-facing RADAR sensor(s) 960, coupled to a dedicated processor, DSP, FPGA, and/or ASIC, that is electrically coupled to driver feedback, such as a display, speaker, and/or vibrating component.

Conventional ADAS systems may be prone to false positive results which may be annoying and distracting to a driver, but typically are not catastrophic, because the ADAS systems alert the driver and allow the driver to decide whether a safety condition truly exists and act accordingly. However, in an autonomous vehicle 900, the vehicle 900 itself must, in the case of conflicting results, decide whether to heed the result from a primary computer or a secondary computer (e.g., a first controller 936 or a second controller 936). For example, in some embodiments, the ADAS system 938 may be a backup and/or secondary computer for providing perception information to a backup computer rationality module. The backup computer rationality monitor may run a redundant diverse software on hardware components to detect faults in perception and dynamic driving tasks. Outputs from the ADAS system 938 may be provided to a supervisory MCU. If outputs from the primary computer and the secondary computer conflict, the supervisory MCU must determine how to reconcile the conflict to ensure safe operation.

In some examples, the primary computer may be configured to provide the supervisory MCU with a confidence score, indicating the primary computer's confidence in the chosen result. If the confidence score exceeds a threshold, the supervisory MCU may follow the primary computer's direction, regardless of whether the secondary computer provides a conflicting or inconsistent result. Where the confidence score does not meet the threshold, and where the primary and secondary computer indicate different results (e.g., the conflict), the supervisory MCU may arbitrate between the computers to determine the appropriate outcome.

The supervisory MCU may be configured to run a neural network(s) that is trained and configured to determine, based on outputs from the primary computer and the secondary computer, conditions under which the secondary computer provides false alarms. Thus, the neural network(s) in the supervisory MCU may learn when the secondary computer's output may be trusted, and when it cannot. For example, when the secondary computer is a RADAR-based FCW system, a neural network(s) in the supervisory MCU may learn when the FCW system is identifying metallic objects that are not, in fact, hazards, such as a drainage grate or manhole cover that triggers an alarm. Similarly, when the secondary computer is a camera-based LDW system, a neural network in the supervisory MCU may learn to override the LDW when bicyclists or pedestrians are present and a lane departure is, in fact, the safest maneuver. In embodiments that include a neural network(s) running on the supervisory MCU, the supervisory MCU may include at least one of a DLA or GPU suitable for running the neural network(s) with associated memory. In preferred embodiments, the supervisory MCU may comprise and/or be included as a component of the SoC(s) 904.

In other examples, ADAS system 938 may include a secondary computer that performs ADAS functionality using traditional rules of computer vision. As such, the secondary computer may use classic computer vision rules (if-then), and the presence of a neural network(s) in the supervisory MCU may improve reliability, safety and performance. For example, the diverse implementation and intentional non-identity makes the overall system more fault-tolerant, especially to faults caused by software (or software-hardware interface) functionality. For example, if there is a software bug or error in the software running on the primary computer, and the non-identical software code running on the secondary computer provides the same overall result, the supervisory MCU may have greater confidence that the overall result is correct, and the bug in software or hardware on primary computer is not causing material error.

In some examples, the output of the ADAS system 938 may be fed into the primary computer's perception block and/or the primary computer's dynamic driving task block. For example, if the ADAS system 938 indicates a forward crash warning due to an object immediately ahead, the perception block may use this information when identifying objects. In other examples, the secondary computer may have its own neural network which is trained and thus reduces the risk of false positives, as described herein.

The vehicle 900 may further include the infotainment SoC 930 (e.g., an in-vehicle infotainment system (IVI)). Although illustrated and described as a SoC, the infotainment system may not be a SoC, and may include two or more discrete components. The infotainment SoC 930 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, Wi-Fi, etc.), and/or information services (e.g., navigation systems, rear-parking assistance, a radio data system, vehicle related information such as fuel level, total distance covered, brake fuel level, oil level, door open/close, air filter information, etc.) to the vehicle 900. For example, the infotainment SoC 930 may radios, disk players, navigation systems, video players, USB and Bluetooth connectivity, carputers, in-car entertainment, Wi-Fi, steering wheel audio controls, hands free voice control, a heads-up display (HUD), an HMI display 934, a telematics device, a control panel (e.g., for controlling and/or interacting with various components, features, and/or systems), and/or other components. The infotainment SoC 930 may further be used to provide information (e.g., visual and/or audible) to a user(s) of the vehicle, such as information from the ADAS system 938, autonomous driving information such as planned vehicle maneuvers, trajectories, surrounding environment information (e.g., intersection information, vehicle information, road information, etc.), and/or other information.

The infotainment SoC 930 may include GPU functionality. The infotainment SoC 930 may communicate over the bus 902 (e.g., CAN bus, Ethernet, etc.) with other devices, systems, and/or components of the vehicle 900. In some examples, the infotainment SoC 930 may be coupled to a supervisory MCU such that the GPU of the infotainment system may perform some self-driving functions in the event that the primary controller(s) 936 (e.g., the primary and/or backup computers of the vehicle 900) fail. In such an example, the infotainment SoC 930 may put the vehicle 900 into a chauffeur to safe stop mode, as described herein.

The vehicle 900 may further include an instrument cluster 932 (e.g., a digital dash, an electronic instrument cluster, a digital instrument panel, etc.). The instrument cluster 932 may include a controller and/or supercomputer (e.g., a discrete controller or supercomputer). The instrument cluster 932 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 930 and the instrument cluster 932. In other words, the instrument cluster 932 may be included as part of the infotainment SoC 930, or vice versa.

FIG. 9D is a system diagram for communication between cloud-based server(s) and the example autonomous vehicle 900 of FIG. 9A, in accordance with some embodiments of the present disclosure. The system 976 may include server(s) 978, network(s) 990, and vehicles, including the vehicle 900. The server(s) 978 may include a plurality of GPUs 984(A)-984(H) (collectively referred to herein as GPUs 984), PCIe switches 982(A)-982(H) (collectively referred to herein as PCIe switches 982), and/or CPUs 980(A)-980(B) (collectively referred to herein as CPUs 980). The GPUs 984, the CPUs 980, and the PCIe switches may be interconnected with high-speed interconnects such as, for example and without limitation, NVLink interfaces 988 developed by NVIDIA and/or PCIe connections 986. In some examples, the GPUs 984 are connected via NVLink and/or NVSwitch SoC and the GPUs 984 and the PCIe switches 982 are connected via PCIe interconnects. Although eight GPUs 984, two CPUs 980, and two PCIe switches are illustrated, this is not intended to be limiting. Depending on the embodiment, each of the server(s) 978 may include any number of GPUs 984, CPUs 980, and/or PCIe switches. For example, the server(s) 978 may each include eight, sixteen, thirty-two, and/or more GPUs 984.

The server(s) 978 may receive, over the network(s) 990 and from the vehicles, image data representative of images showing unexpected or changed road conditions, such as recently commenced road-work. The server(s) 978 may transmit, over the network(s) 990 and to the vehicles, neural networks 992, updated neural networks 992, and/or map information 994, including information regarding traffic and road conditions. The updates to the map information 994 may include updates for the HD map 922, such as information regarding construction sites, potholes, detours, flooding, and/or other obstructions. In some examples, the neural networks 992, the updated neural networks 992, and/or the map information 994 may have resulted from new training and/or experiences represented in data received from any number of vehicles in the environment, and/or based on training performed at a datacenter (e.g., using the server(s) 978 and/or other servers). In various examples, the neural networks 992 and/or updated neural networks 992 may include components of generative world model 242. The neural networks 992 and/or updated neural networks 992 may be trained (at least in part) using simulation data 232, goals 234, commands 236, records 238, and/or datasets 240 generated by data-generation pipeline 122.

The server(s) 978 may be used to train machine learning models (e.g., neural networks, generative world model 242, etc.) based on training data. The training data may be generated by the vehicles, and/or may be generated in a simulation (e.g., using a game engine, data-generation pipeline 122, etc.). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self-learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the vehicles (e.g., transmitted to the vehicles over the network(s) 990, and/or the machine learning models may be used by the server(s) 978 to remotely monitor the vehicles.

In some examples, the server(s) 978 may receive data from the vehicles and apply the data to up-to-date real-time neural networks for real-time intelligent inferencing. The server(s) 978 may include deep-learning supercomputers and/or dedicated AI computers powered by GPU(s) 984, such as a DGX and DGX Station machines developed by NVIDIA. However, in some examples, the server(s) 978 may include deep learning infrastructure that use only CPU-powered datacenters.

The deep-learning infrastructure of the server(s) 978 may be capable of fast, real-time inferencing, and may use that capability to evaluate and verify the health of the processors, software, and/or associated hardware in the vehicle 900. For example, the deep-learning infrastructure may receive periodic updates from the vehicle 900, such as a sequence of images and/or objects that the vehicle 900 has located in that sequence of images (e.g., via computer vision and/or other machine learning object classification techniques). The deep-learning infrastructure may run its own neural network to identify the objects and compare them with the objects identified by the vehicle 900 and, if the results do not match and the infrastructure concludes that the AI in the vehicle 900 is malfunctioning, the server(s) 978 may transmit a signal to the vehicle 900 instructing a fail-safe computer of the vehicle 900 to assume control, notify the passengers, and complete a safe parking maneuver.

For inferencing, the server(s) 978 may include the GPU(s) 984 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAS, and other processors may be used for inferencing.

### Example Computing Device

FIG. 10 is a block diagram of an example computing device(s) 1000 suitable for use in implementing some embodiments of the present disclosure. Computing device 1000 may include an interconnect system 1002 that directly or indirectly couples the following devices: memory 1004, one or more central processing units (CPUs) 1006, one or more graphics processing units (GPUs) 1008, a communication interface 1010, input/output (I/O) ports 1012, input/output components 1014, a power supply 1016, one or more presentation components 1018 (e.g., display(s)), and one or more logic units 1020. In at least one embodiment, the computing device(s) 1000 may comprise one or more virtual machines (VMs), and/or any of the components thereof may comprise virtual components (e.g., virtual hardware components). For non-limiting examples, one or more of the GPUs 1008 may comprise one or more vGPUs, one or more of the CPUs 1006 may comprise one or more vCPUs, and/or one or more of the logic units 1020 may comprise one or more virtual logic units. As such, a computing device(s) 1000 may include discrete components (e.g., a full GPU dedicated to the computing device 1000), virtual components (e.g., a portion of a GPU dedicated to the computing device 1000), or a combination thereof.

Although the various blocks of FIG. 10 are shown as connected via the interconnect system 1002 with lines, this is not intended to be limiting and is for clarity only. For example, in some embodiments, a presentation component 1018, such as a display device, may be considered an I/O component 1014 (e.g., if the display is a touch screen). As another example, the CPUs 1006 and/or GPUs 1008 may include memory (e.g., the memory 1004 may be representative of a storage device in addition to the memory of the GPUs 1008, the CPUs 1006, and/or other components). In other words, the computing device of FIG. 10 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 10.

The interconnect system 1002 may represent one or more links or busses, such as an address bus, a data bus, a control bus, or a combination thereof. The interconnect system 1002 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 1006 may be directly connected to the memory 1004. Further, the CPU 1006 may be directly connected to the GPU 1008. Where there is direct, or point-to-point connection between components, the interconnect system 1002 may include a PCIe link to carry out the connection. In these examples, a PCI bus need not be included in the computing device 1000.

The memory 1004 may include any of a variety of computer-readable media. The computer-readable media may be any available media that may be accessed by the computing device 1000. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 1004 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 1000. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 1006 may be configured to execute at least some of the computer-readable instructions to control one or more components of the computing device 1000 to perform one or more of the methods and/or processes described herein. The CPU(s) 1006 may each include one or more cores (e.g., one, two, four, eight, twenty-eight, seventy-two, etc.) that are capable of handling a multitude of software threads simultaneously. The CPU(s) 1006 may include any type of processor, and may include different types of processors depending on the type of computing device 1000 implemented (e.g., processors with fewer cores for mobile devices and processors with more cores for servers). For example, depending on the type of computing device 1000, the processor may be an Advanced RISC Machines (ARM) processor implemented using Reduced Instruction Set Computing (RISC) or an x86 processor implemented using Complex Instruction Set Computing (CISC). The computing device 1000 may include one or more CPUs 1006 in addition to one or more microprocessors or supplementary co-processors, such as math co-processors.

In addition to or alternatively from the CPU(s) 1006, the GPU(s) 1008 may be configured to execute at least some of the computer-readable instructions to control one or more components of the computing device 1000 to perform one or more of the methods and/or processes described herein. For example, the CPU(s) 1006 and/or GPU(s) 1008 may be used to execute data-generation pipeline 122, training engine 124, and/or execution engine 126. One or more of the GPU(s) 1008 may be an integrated GPU (e.g., with one or more of the CPU(s) 1006 and/or one or more of the GPU(s) 1008 may be a discrete GPU. In embodiments, one or more of the GPU(s) 1008 may be a coprocessor of one or more of the CPU(s) 1006. The GPU(s) 1008 may be used by the computing device 1000 to render graphics (e.g., 3D graphics) or perform general purpose computations. For example, the GPU(s) 1008 may be used for General-Purpose computing on GPUs (GPGPU). The GPU(s) 1008 may include hundreds or thousands of cores that are capable of handling hundreds or thousands of software threads simultaneously. The GPU(s) 1008 may generate pixel data for output images in response to rendering commands (e.g., rendering commands from the CPU(s) 1006 received via a host interface). The GPU(s) 1008 may include graphics memory, such as display memory, for storing pixel data or any other suitable data, such as GPGPU data. The display memory may be included as part of the memory 1004. The GPU(s) 1008 may include two or more GPUs operating in parallel (e.g., via a link). The link may directly connect the GPUs (e.g., using NVLINK) or may connect the GPUs through a switch (e.g., using NVSwitch). When combined together, each GPU 1008 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 1006 and/or the GPU(s) 1008, the logic unit(s) 1020 may be configured to execute at least some of the computer-readable instructions to control one or more components of the computing device 1000 to perform one or more of the methods and/or processes described herein. In embodiments, the CPU(s) 1006, the GPU(s) 1008, and/or the logic unit(s) 1020 may discretely or jointly perform any combination of the methods, processes and/or portions thereof. One or more of the logic units 1020 may be part of and/or integrated in one or more of the CPU(s) 1006 and/or the GPU(s) 1008 and/or one or more of the logic units 1020 may be discrete components or otherwise external to the CPU(s) 1006 and/or the GPU(s) 1008. In embodiments, one or more of the logic units 1020 may be a coprocessor of one or more of the CPU(s) 1006 and/or one or more of the GPU(s) 1008.

Examples of the logic unit(s) 1020 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 1010 may include one or more receivers, transmitters, and/or transceivers that enable the computing device 1000 to communicate with other computing devices via an electronic communication network, included wired and/or wireless communications. The communication interface 1010 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 1020 and/or communication interface 1010 may include one or more data processing units (DPUs) to transmit data received over a network and/or through interconnect system 1002 directly to (e.g., a memory of) one or more GPU(s) 1008.

The I/O ports 1012 may enable the computing device 1000 to be logically coupled to other devices including the I/O components 1014, the presentation component(s) 1018, and/or other components, some of which may be built in to (e.g., integrated in) the computing device 1000. Illustrative I/O components 1014 include a microphone, mouse, keyboard, joystick, game pad, game controller, satellite dish, scanner, printer, wireless device, etc. The I/O components 1014 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 1000. The computing device 1000 may be include depth cameras, such as stereoscopic camera systems, infrared camera systems, RGB camera systems, touchscreen technology, and combinations of these, for gesture detection and recognition. Additionally, the computing device 1000 may include accelerometers or gyroscopes (e.g., as part of an inertia measurement unit (IMU)) that enable detection of motion. In some examples, the output of the accelerometers or gyroscopes may be used by the computing device 1000 to render immersive augmented reality or virtual reality.

The power supply 1016 may include a hard-wired power supply, a battery power supply, or a combination thereof. The power supply 1016 may provide power to the computing device 1000 to enable the components of the computing device 1000 to operate.

The presentation component(s) 1018 may include a display (e.g., a monitor, a touch screen, a television screen, a heads-up-display (HUD), other display types, or a combination thereof), speakers, and/or other presentation components. The presentation component(s) 1018 may receive data from other components (e.g., the GPU(s) 1008, the CPU(s) 1006, DPUs, etc.), and output the data (e.g., as an image, video, sound, etc.).

### Example Data Center

FIG. 11 illustrates an example data center 1100 that may be used in at least one embodiments of the present disclosure. The data center 1100 may include a data center infrastructure layer 1110, a framework layer 1120, a software layer 1130, and/or an application layer 1140.

As shown in FIG. 11, the data center infrastructure layer 1110 may include a resource orchestrator 1112, grouped computing resources 1114, and node computing resources (“node C.R.s”) 1116(1)-1116(N), where “N” represents any whole, positive integer. In at least one embodiment, node C.R.s 1116(1)-1116(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 1116(1)-1116(N) may correspond to a server having one or more of the above-mentioned computing resources. In addition, in some embodiments, the node C.R.s 1116(1)-11161(N) may include one or more virtual components, such as vGPUs, vCPUs, and/or the like, and/or one or more of the node C.R.s 1116(1)-1116(N) may correspond to a virtual machine (VM).

In at least one embodiment, grouped computing resources 1114 may include separate groupings of node C.R.s 1116 housed within one or more racks (not shown), or many racks housed in data centers at various geographical locations (also not shown). Separate groupings of node C.R.s 1116 within grouped computing resources 1114 may include grouped compute, network, memory or storage resources that may be configured or allocated to support one or more workloads. In at least one embodiment, several node C.R.s 1116 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 1112 may configure or otherwise control one or more node C.R.s 1116(1)-1116(N) and/or grouped computing resources 1114. In at least one embodiment, resource orchestrator 1112 may include a software design infrastructure (SDI) management entity for the data center 1100. The resource orchestrator 1112 may include hardware, software, or some combination thereof.

In at least one embodiment, as shown in FIG. 11, framework layer 1120 may include a job scheduler 1133, a configuration manager 1134, a resource manager 1136, and/or a distributed file system 1138. The framework layer 1120 may include a framework to support software 1132 of software layer 1130 and/or one or more application(s) 1142 of application layer 1140. The software 1132 or application(s) 1142 may respectively include web-based service software or applications, such as those provided by Amazon Web Services, Google Cloud and Microsoft Azure. The framework layer 1120 may be, but is not limited to, a type of free and open-source software web application framework such as Apache Spark™ (hereinafter “Spark”) that may utilize distributed file system 1138 for large-scale data processing (e.g., “big data”). In at least one embodiment, job scheduler 1133 may include a Spark driver to facilitate scheduling of workloads supported by various layers of data center 1100. The configuration manager 1134 may be capable of configuring different layers such as software layer 1130 and framework layer 1120 including Spark and distributed file system 1138 for supporting large-scale data processing. The resource manager 1136 may be capable of managing clustered or grouped computing resources mapped to or allocated for support of distributed file system 1138 and job scheduler 1133. In at least one embodiment, clustered or grouped computing resources may include grouped computing resource 1114 at data center infrastructure layer 1110. The resource manager 1136 may coordinate with resource orchestrator 1112 to manage these mapped or allocated computing resources.

In at least one embodiment, software 1132 included in software layer 1130 may include software used by at least portions of node C.R.s 1116(1)-1116(N), grouped computing resources 1114, and/or distributed file system 1138 of framework layer 1120. One or more types of software may include, but are not limited to, Internet web page search software, e-mail virus scan software, database software, and streaming video content software.

In at least one embodiment, application(s) 1142 included in application layer 1140 may include one or more types of applications used by at least portions of node C.R.s 1116(1)-1116(N), grouped computing resources 1114, and/or distributed file system 1138 of framework layer 1120. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 1134, resource manager 1136, and resource orchestrator 1112 may implement any number and type of self-modifying actions based on any amount and type of data acquired in any technically feasible fashion. Self-modifying actions may relieve a data center operator of data center 1100 from making possibly bad configuration decisions and possibly avoiding underutilized and/or poor performing portions of a data center.

The data center 1100 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 1100. In at least one embodiment, trained or deployed machine learning models corresponding to one or more neural networks may be used to infer or predict information using resources described above with respect to the data center 1100 by using weight parameters calculated through one or more training techniques, such as but not limited to those described herein.

In at least one embodiment, the data center 1100 may use CPUs, application-specific integrated circuits (ASICs), GPUs, FPGAs, and/or other hardware (or virtual compute resources corresponding thereto) to perform training and/or inferencing using above-described resources. For example, the data center 1100 may execute one or more instances of data-generation pipeline 122, training engine 124, and/or execution engine 126. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 1000 of FIG. 10—e.g., each device may include similar components, features, and/or functionality of the computing device(s) 1000. In addition, where backend devices (e.g., servers, NAS, etc.) are implemented, the backend devices may be included as part of a data center 1100, an example of which is described in more detail herein with respect to FIG. 11.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 1000 described herein with respect to FIG. 10. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

In some embodiments, the systems and methods described herein may be performed within a simulation environment (e.g., NVIDIA's DriveSIM, NVIDIA's ISAAC GYM, NVIDIA's ISAAC SIM, etc.) using simulated data (e.g., simulated sensor data of simulated sensors of a virtual or simulated machine). For example, simulated sensor data may be used (e.g., processed using one or more machine learning models, neural networks, etc.) to identify, detect, and/or classify lane lines, road boundary lines, other lines, vertical structures/features, occupancy maps, odometry values, images, semantic labels, bounding shapes, etc. within the simulation environment using points of a curve and/or one or more curve fitting algorithms, and may use this information to perform operations (e.g., control, navigation, planning, etc. operations) associated with the virtual machine within the environment. These simulated operations may be used to test performance of the underlying algorithms, systems, and/or processes prior to deploying them in the real-world. In some instances, the simulation may be used to generate synthetic training data—e.g., training data including regions of interest and/or sub-regions of interest from within the simulation. In some embodiments, other methods may be used in addition or alternatively from a simulation to generate synthetic training data. For example, the synthetic training data may be generated using NeRFs, Gaussian splat techniques, diffusion models, electrostatic models (e.g., Poisson flow generative models (PFGMs), etc. The synthetic training data (in addition to or alternatively from real-world data) may then be processed to determine geometry, curvature, semantic information, classification information, and/or other information related to features of interest, such as lines, longitudinal features (e.g., poles), and/or other features within a driving environment, a warehouse, etc., for example. In any example, such as where a simulation environment is used for testing, validation, training, etc., the simulation environment and/or associated training data may be rendered or otherwise generated using one or more light transport algorithms-such as ray-tracing and/or path-tracing algorithms. In some embodiments, the simulation environment and/or one or more objects, features, or components thereof may be generated or managed within a three-dimensional (3D) content collaboration platform (e.g., NVIDIA's OMNIVERSE) for industrial digitalization, generative physical AI, and/or other use cases, applications, or services. For example, the content collaboration platform or system may include a system that uses universal scene descriptor (USD) (e.g., OpenUSD) data for managing objects, features, scenes, etc. within a simulated environment, digital environment, etc. The platform may include real physics simulation, such as using NVIDIA's PhysX SDK, in order to simulate real physics and physical interactions with simulations hosted by the platform. The platform may integrate OpenUSD along with ray tracing/path tracing/light transport simulation (e.g., NVIDIA's RTX rendering technologies) into software tools and simulation workflows for building, training, deploying, or testing AI systems-such as systems for testing, validating, training (e.g., machine learning models, neural networks, etc.), and/or other tasks related to automotive, robot, machine, or other applications.

In some embodiments, teleoperation or remote control of a vehicle or other machine may be performed using a remote control or teleoperation system. For example, the systems and methods described herein may be used to identify lane lines, road boundary lines, longitudinal features, occupancy maps, semantic labels, bounding shapes, etc. that may be included in a visualization or mapping of an environment to aid a remote operator in controlling—or providing waypoints or other indications of control or navigation—an autonomous or semi-autonomous machine through an environment.

In some embodiments, the system and methods described herein may be deployed in a robotics application. For example, a robot or robotic system may include one or more onboard processors, memory, and/or storage (e.g., for storing control algorithms, sensor data, and one or more machine learning models). The robotic system may use these processors to execute one or more machine learning models (e.g., language models) that allow it to perform complex tasks autonomously or semi-autonomously, such as interacting with and/or manipulating static and/or dynamic objects, or navigating environments using sensors such as cameras, LiDAR, RADAR, ultrasonic sensors, and more. The system may use sensor fusion techniques to combine data from multiple sensors (e.g., cameras, infrared, LiDAR, RADAR, accelerometers) to create a comprehensive model of the robot's surroundings. This data may be processed locally on the robot or sent to remote servers for more computationally intensive tasks, such as 3D mapping or SLAM (Simultaneous Localization and Mapping). In one or more embodiments, data from individual robots (e.g., sensor data, task status, or environmental conditions) may be uploaded to the cloud, where centralized AI models can analyze and distribute optimized commands to an entire fleet. In some embodiments, the machine learning model(s) described herein may be used to allow the robot to perceive and reason about the environment and/or communicate with one or more other robots and/or persons in an environment. In some embodiments, the robot may communicate (e.g., using one or more network interface cards (NICs) and/or data processing units (DPUs)) with one or more locally hosted servers/computing devices and/or with one or more remotely located servers/computing devices (e.g., in one or more data centers).

In some examples, the machine learning model(s) described herein may be packaged as a microservice—such an inference microservice (e.g., NVIDIA NIMs)—which may include a container (e.g., an operating system (OS)-level virtualization package) that may include an application programming interface (API) layer, a server layer, a runtime layer, and/or a model “engine.” For example, the inference microservice may include the container itself and the model(s) (e.g., weights and biases). In some instances, such as where the machine learning model(s) is small enough (e.g., has a small enough number of parameters), the model(s) may be included within the container itself. In other examplessuch as where the model(s) is large—the model(s) may be hosted/stored in the cloud (e.g., in a data center) and/or may be hosted on-premises and/or at the edge (e.g., on a local server or computing device, but outside of the container). In such embodiments, the model(s) may be accessible via one or more APIs-such as REST APIs. As such, and in some embodiments, the machine learning model(s) described herein may be deployed as an inference microservice to accelerate deployment of a model(s) on any cloud, data center, or edge computing system, while ensuring the data is secure. For example, the inference microservice may include one or more APIs, a pre-configured container for simplified deployment, an optimized inference engine (e.g., built using a standardized AI model deployment an execution software, such as NVIDIA's Triton Inference Server, and/or one or more APIs for high performance deep learning inference, which may include an inference runtime and model optimizations that deliver low latency and high throughput for production applications-such as NVIDIA's TensorRT), and/or enterprise management data for telemetry (e.g., including identity, metrics, health checks, and/or monitoring). The machine learning model(s) described herein may be included as part of the microservice along with an accelerated infrastructure with the ability to deploy with a single command and/or orchestrate and auto-scale with a container orchestration system on accelerated infrastructure (e.g., on a single device up to data center scale). As such, the inference microservice may include the machine learning model(s) (e.g., that has been optimized for high performance inference), an inference runtime software to execute the machine learning model(s) and provide outputs/responses to inputs (e.g., user queries, prompts, etc.), and enterprise management software to provide health checks, identity, and/or other monitoring. In some embodiments, the inference microservice may include software to perform in-place replacement and/or updating to the machine learning model(s). When replacing or updating, the software that performs the replacement/updating may maintain user configurations of the inference runtime software and enterprise management software.

In sum, the disclosed techniques train and execute a multimodal generative world model to perform end-to-end navigation and other tasks for an AMR and/or another type of machine. The multimodal generative world model directly maps inputs such as (but not limited to) camera images, velocities, global guidance, and/or robot states to multimodal outputs such as (but not limited to) semantic segmentations, paths, and/or navigation commands. The multimodal generative world model includes a set of encoders that convert the inputs into an embedding in a latent vector space and a feature compressor that aggregates embeddings of the inputs into a single embedded output.

The multimodal generative world model also includes a posterior estimator and a prior estimator. The posterior estimator generates a latent state representing the world around the machine at a current timestep based on input that includes (i) the embedded output from the feature compressor, (ii) an action performed by the machine at a previous timestep, and/or (iii) a history of latent states up to the previous timestep. The latent state for the current timestep is converted by a set of decoders and an action policy into a semantic segmentation, perspective view, set of actions, and/or other multimodal outputs that can be used by the machine to navigate and/or perform other tasks during the current time step.

The prior estimator generates a latent state for one or more future time steps, given input that includes (i) a history that has been updated with the latent state for the current time step (e.g., from the posterior estimator) and (ii) an action associated with the current time step (e.g., as generated by an action policy from the latent state for the current time step). The latent state for a given future timestep may be converted by the set of decoders and the action policy into multimodal outputs associated with that future time step. These multimodal outputs thus represent predictions of a “future” world associated with the machine and can be used to train the multimodal generative world model and/or perform other tasks related to the predictions.

The disclosed techniques also include a data-generation pipeline that generates a synthetic dataset for the purpose of training, evaluating, and/or testing the multimodal generative world model, other types of machine learning models that can be used by AMRs and/or other machine types to perform tasks, hardware configurations for the machines, and/or other components of the machines. The data-generation pipeline includes a simulator that performs various types of simulations related to a machine (e.g., a robot) navigating within an environment (e.g., a warehouse). Data generated by the simulator based on the simulations includes (but is not limited to) rendered images of the environment around the machine (e.g., from the perspective of one or more cameras on the machine and/or a birds-eye visualization), semantic labels (e.g., segmentation maps, detected objects, bounding shapes, etc.) associated with the images, a state of the machine (e.g., position, heading, velocity, etc.), and/or an occupancy map of free and/or occupied space within the environment. The data-generation pipeline also includes a goal generator that determines a goal within the occupancy map, such as (but not limited to) a target location to navigate to within the environment.

The data-generation pipeline additionally includes a planner that generates a command to the machine to take an action related to the goal, such as a linear and/or angular velocity that moves the machine toward the goal. The command is sent to the simulator, which updates the state of the machine, rendered images, semantic labels, occupancy map, and/or other data based on the action. The simulator also sends some or all of the updated data to the planner to allow the planner to generate a new command based on the updated data and the goal from the goal generator. This process repeats until the goal is reached by the machine, a certain number of time steps has been executed within the simulation, and/or another condition indicating the end of the simulation is met.

The data-generation pipeline further includes a logger that records and synchronizes data outputted by the other components across time steps. For example, the logger may log data from the other components in the order in which the corresponding events occur within the simulation. The logger may also downsample some or all of the data (e.g., on a spatial and/or temporal basis) to reduce the size of the logged data.

A post-processor in the data-generation pipeline adapts the generated data to various machine learning models and/or use cases. For example, the post-processor may resample, compress, format, and/or otherwise convert the generated data into a form that can be used to train and/or evaluate a machine learning model, hardware configuration, and/or other components of the machine.

The data-generation pipeline can be configured and/or customized via one or more sets of configuration parameters. For example, the configuration parameters may include a unique name and/or identifier for a given scenario (e.g., a combination of a particular environment, machine, goal, policy, etc.) under which data is to be generated and collected. The configuration parameters may also be used to customize the environment and/or type of machine to be simulated, the goal, the type of planner, the type of data to log, the frequency with which the data is logged, and/or the way in which the logged data is converted into a format that is suitable for training and/or evaluating a machine learning model and/or another component of the machine. Different sets of configuration parameters can be used to launch different instances of the data-generation pipeline (e.g., in parallel on multiple nodes of a distributed system) to generate data that captures different scenarios related to navigation and/or other types of tasks performed by machines in environments.

One advantage of the disclosed techniques relative to prior approaches is the ability to use a single generative world model to convert multiple sensory and/or state-based inputs associated with a machine into multimodal outputs that can be used by the machine to navigate and/or perform other tasks. The disclosed techniques may thus mitigate and/or avert issues related to conventional approaches that use complex integrations across multiple modules to perform tasks, such as (but not limited to) propagation of errors across modules that lead to reduced navigation performance, a lack of holistic understanding that interferes with the ability to make contextually aware decisions, significant re-engineering and/or adjustment of multiple individual modules to adapt the navigation system to new tasks and/or environments, and/or redundant and/or sequential processing that negatively impacts the use of the navigation systems in real-time and/or time-sensitive applications. Another advantage of the disclosed techniques is the ability to generate synthetic data that spans diverse environments, goals, machine types, behaviors, and/or other types of data related to navigation and/or other tasks performed by machines. This synthetic data may be used to train, test, and/or evaluate machine learning models and/or other components of the machines, thereby facilitating fault tolerance and/or generalization of the machines to different scenarios and/or use cases.

1. In some embodiments, a method comprises converting a set of sensory inputs obtained using one or more sensors of a machine at a current time step into a set of embedded features; generating, via execution of one or more neural networks and based at least on the set of embedded features, a history of states preceding the current time step, a first set of actions associated with a previous time step, and one or more states associated with the current time step; converting, via execution of the one or more neural networks, the one or more states into a set of predictions associated with the current time step; and performing, by the machine, a second set of actions associated with the current time step based at least on the set of predictions.

2. The method of clause 1, further comprising generating, via execution of the one or more neural networks, one or more additional states associated with a next time step following the current time step; computing one or more losses based at least on the set of predictions, the one or more states, and the one or more additional states; and updating one or more parameters of the one or more neural networks based at least on the one or more losses.

3. The method of any of clauses 1-2, wherein the generating the one or more additional states comprises generating an additional history of states up to the current time step based at least on the one or more states; and generating, via execution of a prior estimator included in the one or more neural networks, the one or more additional states based at least on the additional history of states and the second set of actions.

4. The method of any of clauses 1-3, wherein the one or more losses comprise one or more differences between the set of predictions and a set of ground truth observations associated with the current time step.

5. The method of any of clauses 1-4, wherein the one or more losses comprise a divergence between a prior distribution associated with the one or more additional states and a posterior distribution associated with the one or more states.

6. The method of any of clauses 1-5, wherein the generating the one or more states comprises generating, via execution of a posterior estimator included in the one or more neural networks based at least on the set of embedded features, a current state that is (i) associated with the current time step and (ii) included in the one or more states; and combining the current state and the history of states into a latent state that is (i) associated with the current time step and (ii) included in the one or more states.

7. The method of any of clauses 1-6, wherein the current state is further generated based at least on (i) the history of states and (ii) the first set of actions.

8. The method of any of clauses 1-7, wherein the set of sensory inputs comprises at least one of an image of an environment around the machine, a state of the machine, a specification for the machine, or a global guidance associated with the second set of actions.

9. The method of any of clauses 1-8, wherein the set of predictions comprises at least one of a semantic segmentation, a trajectory for the machine, one or more images associated with one or more time steps following the current time step, or the second set of actions.

10. The method of any of clauses 1-9, wherein the second set of actions comprises at least one of a forward movement, a backward movement, a left turn, or a right turn.

11. In some embodiments, at least one processor comprises processing circuitry to cause performance of operations comprising converting a set of sensory inputs obtained using a machine at a current time step into a set of embedded features; generating, via execution of one or more neural networks, one or more states associated with the current time step based at least on the set of embedded features; converting, via execution of the one or more neural networks, the one or more states into a set of predictions associated with the current time step; and performing, by the machine, a second set of actions associated with the current time step based at least on the set of predictions.

12. The at least one processor of clause 11, wherein the operations further comprise generating, via execution of the one or more neural networks, one or more additional states associated with a next time step following the current time step; computing one or more losses based at least on the set of predictions, the one or more states, and the one or more additional states; and updating one or more parameters of the one or more neural networks based at least on the one or more losses.

13. The at least one processor of any of clauses 11-12, wherein the updating the one or more parameters of the one or more neural networks comprises computing a first loss based at least on the set of predictions and a set of ground truth observations associated with the current time step; updating a first set of parameters included in the one or more neural networks based at least on the first loss; computing a second loss between a prior distribution associated with the one or more additional states and a posterior distribution associated with the one or more states; and updating a second set of parameters included in the one or more neural networks based at least on the second loss.

14. The at least one processor of any of clauses 11-13, wherein the updating the one or more parameters of the one or more neural networks further comprises after the first set of parameters and the second set of parameters have been updated, updating a third set of parameters included in the one or more neural networks based at least on a third loss that is computed between one or more actions generated based at least on the third set of parameters and one or more additional actions associated with a teacher policy.

15. The at least one processor of any of clauses 11-14, wherein the first set of parameters is included in a posterior estimator neural network and one or more encoder neural networks; and the second set of parameters is included in a prior estimator neural network.

16. The at least one processor of any of clauses any of clauses 11-15, wherein the converting the set of sensory inputs into the set of embedded features comprises converting, via execution of one or more encoder neural networks, each sensory input included in the set of sensory inputs into a different embedding; and combining the different embeddings of the set of sensory inputs into an input embedding associated with the set of sensory inputs.

17. The at least one processor of any of clauses 11-16, wherein the machine comprises at least one of a quadruped robot, a humanoid robot, a differential drive system, an Ackermann drive system, a warehouse robot, or a forklift.

18. The at least one processor of any of clauses 11-17, wherein the at least one processor is comprised in at least one of a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system for generating or presenting at least one of virtual reality content, augmented reality content, or mixed reality content; a system implemented using a robot; a system for performing one or more conversational AI operations; a system for performing one or more generative AI operations; a system implementing one or more large language models (LLMs); a system implementing one or more vision language models (VLMs); a system implementing one or more multimodal language models; a system for generating synthetic data; a system incorporating one or more virtual machines (VMs); a system implemented at least partially in a data center; or a system implemented at least partially using cloud computing resources.

19. In some embodiments, a system comprises one or more processors to cause one or more actions to be performed by a machine based at least on one or more states outputted using a generative world model, the one or more states being generated based on at least one of a set of sensory inputs received using the machine, a history of states associated with the machine, or one or more previous actions performed by the machine.

20. The system of clause 19, wherein the system is comprised in at least one of a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system for generating or presenting at least one of virtual reality content, augmented reality content, or mixed reality content; a system implemented using a robot; a system for performing one or more conversational AI operations; a system for performing one or more generative AI operations; a system implementing one or more large language models (LLMs); a system implementing one or more vision language models (VLMs); a system implementing one or more multimodal language models; a system for generating synthetic data; a system incorporating one or more virtual machines (VMs); a system implemented at least partially in a data center; or a system implemented at least partially using cloud computing resources.

21. In some embodiments, a method comprises generating, via one or more simulations, simulation data associated with operation of a first machine in an environment; determining a command to the first machine based at least on the simulation data and a goal associated with the first machine; updating the simulation data based at least on the command; storing the simulation data, the command, and the updated simulation data in one or more data records; and causing a second machine to perform one or more actions based at least on the one or more data records.

22. The method of clause 21, further comprising generating additional simulation data and one or more additional commands associated with operation of a third machine in a second environment; and storing the simulation data and the one or more additional commands in one or more additional data records.

23. The method of any of clauses 21-22, further comprising determining a set of statistics associated with the one or more data records and the one or more additional data records; and storing the set of statistics in metadata associated with the one or more data records or the one or more additional data records.

24. The method of any of clauses 21-23, wherein the set of statistics comprises at least one of a number of instances of a semantic class, a time interval between the simulation data and the updated simulation data, an overall distance associated with operation of the first machine and the third machine, or a distribution of the command and the one or more additional commands.

25. The method of any of clauses 21-24, further comprising determining a location corresponding to the goal based at least on (i) a sampling strategy and (ii) one or more regions specified within an occupancy map of the environment.

26. The method of any of clauses 21-25, wherein the storing the simulation data, the command, and the updated simulation data comprises resampling at least one of the simulation data, the command, or the updated simulation data based at least on a sampling frequency associated with the one or more data records.

27. The method of any of clauses 21-26, wherein the causing the second machine to perform the one or more actions comprises generating, via execution of one or more neural networks, a set of predictions based at least on the simulation data; updating one or more parameters of the one or more neural networks based at least on one or more losses computed from the one or more data records and the set of predictions to generate one or more trained neural networks; and generating, via execution of the one or more trained neural networks, the one or more actions based at least on a set of sensory inputs received by the second machine.

28. The method of any of clauses 21-27, wherein the causing the second machine to perform the one or more actions comprises executing the second machine as a digital twin using the simulation data, the command, and the updated simulation data.

29. The method of any of clauses 21-28, wherein the one or more actions comprise at least one of a forward movement, a backward movement, a left turn, or a right turn.

30. The method of any of clauses 21-29, wherein the simulation data comprises at least one of an image of the environment, a point cloud associated with the environment, an occupancy map associated with the environment, a semantic segmentation of the environment, one or more bounding boxes associated with one or more objects in the environment, a position of the first machine, a heading of the first machine, or a velocity of the first machine.

31. In some embodiments, at least one processor comprises processing circuitry to cause performance of operations comprising generating, via one or more simulations, simulation data associated with operation of a first machine in an environment; determining a command to the first machine based at least on the simulation data and a goal associated with the first machine; updating the simulation data based at least on the command; storing the simulation data, the command, and the updated simulation data in one or more data records; and causing a second machine to perform one or more actions based at least on the one or more data records.

32. The at least one processor of clause 31, wherein the operations further comprise generating additional simulation data and one or more additional commands associated with operation of the first machine in a second environment; and storing the simulation data and the one or more additional commands in one or more additional data records.

33. The at least one processor of any of clauses 31-32, wherein the operations further comprise causing the second machine to perform the one or more actions based at least on the one or more additional data records.

34. The at least one processor of any of clauses any of clauses 31-33, wherein the determining the command comprises generating, via a policy for the first machine, the command based at least on the goal and at least a portion of the simulation data.

35. The at least one processor of any of clauses 31-34, wherein the storing the simulation data, the command, and the updated simulation data comprises downsampling at least one of the simulation data, the command, or the updated simulation data based at least on one or more configuration parameters associated with the one or more data records.

36. The at least one processor of any of clauses 31-35, wherein the operations further comprise initializing the one or more simulations using at least one of a type of the first machine, a model of the first machine, one or more sensors included in the first machine, an initial pose of the first machine, a 3D scene corresponding to the environment, one or more objects in the environment, or one or more properties of the environment.

37. The at least one processor of any of clauses 31-36, wherein the first machine comprises at least one of a quadruped robot, a humanoid robot, a differential drive system, an Ackermann drive system, or a forklift.

38. The at least one processor of any of clauses 31-37, wherein the at least one processor is comprised in at least one of a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system for generating or presenting at least one of virtual reality content, augmented reality content, or mixed reality content; a system implemented using a robot; a system for performing one or more conversational AI operations; a system for performing one or more generative AI operations; a system implementing one or more large language models (LLMs); a system implementing one or more vision language models (VLMs); a system implementing one or more multimodal language models; a system for generating synthetic data; a system incorporating one or more virtual machines (VMs); a system implemented at least partially in a data center; or a system implemented at least partially using cloud computing resources.

39. In some embodiments, a system comprises one or more processors to perform operations comprising generating a synthetic dataset based at least on a simulation of a machine in an environment, a goal associated with operation of the machine in the environment, and one or more commands to the machine, wherein the simulation is generated using one or more light transport simulation algorithms within a collaborative content creation platform for three-dimensional assets that uses a universal scene descriptor (USD) data format.

40. The system of clause 39, wherein the system is comprised in at least one of a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system for generating or presenting at least one of virtual reality content, augmented reality content, or mixed reality content; a system implemented using a robot; a system for performing one or more conversational AI operations; a system for performing one or more generative AI operations; a system implementing one or more large language models (LLMs); a system implementing one or more vision language models (VLMs); a system implementing one or more multimodal language models; a system for generating synthetic data; a system incorporating one or more virtual machines (VMs); a system implemented at least partially in a data center; or a system implemented at least partially using cloud computing resources.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A method comprising:
converting a set of sensory inputs obtained using one or more sensors of a machine at a current time step into a set of embedded features;
generating, via execution of one or more neural networks and based at least on the set of embedded features, a history of states preceding the current time step, a first set of actions associated with a previous time step, and one or more states associated with the current time step;
converting, via execution of the one or more neural networks, the one or more states into a set of predictions associated with the current time step; and
performing, by the machine, a second set of actions associated with the current time step based at least on the set of predictions.

2. The method of claim 1, further comprising:
generating, via execution of the one or more neural networks, one or more additional states associated with a next time step following the current time step;
computing one or more losses based at least on the set of predictions, the one or more states, and the one or more additional states; and
updating one or more parameters of the one or more neural networks based at least on the one or more losses.

3. The method of claim 2, wherein the generating the one or more additional states comprises:
generating an additional history of states up to the current time step based at least on the one or more states; and
generating, via execution of a prior estimator included in the one or more neural networks, the one or more additional states based at least on the additional history of states and the second set of actions.

4. The method of claim 2, wherein the one or more losses comprise one or more differences between the set of predictions and a set of ground truth observations associated with the current time step.

5. The method of claim 2, wherein the one or more losses comprise a divergence between a prior distribution associated with the one or more additional states and a posterior distribution associated with the one or more states.

6. The method of claim 1, wherein the generating the one or more states comprises:
generating, via execution of a posterior estimator included in the one or more neural networks based at least on the set of embedded features, a current state that is (i) associated with the current time step and (ii) included in the one or more states; and
combining the current state and the history of states into a latent state that is (i) associated with the current time step and (ii) included in the one or more states.

7. The method of claim 6, wherein the current state is further generated based at least on (i) the history of states and (ii) the first set of actions.

8. The method of claim 1, wherein the set of sensory inputs comprises at least one of an image of an environment around the machine, a state of the machine, a specification for the machine, or a global guidance associated with the second set of actions.

9. The method of claim 1, wherein the set of predictions comprises at least one of a semantic segmentation, a trajectory for the machine, one or more images associated with one or more time steps following the current time step, or the second set of actions.

10. The method of claim 1, wherein the second set of actions comprises at least one of a forward movement, a backward movement, a left turn, or a right turn.

11. At least one processor comprising:
processing circuitry to cause performance of operations comprising:
converting a set of sensory inputs obtained using a machine at a current time step into a set of embedded features;
generating, via execution of one or more neural networks, one or more states associated with the current time step based at least on the set of embedded features;
converting, via execution of the one or more neural networks, the one or more states into a set of predictions associated with the current time step; and
performing, by the machine, a second set of actions associated with the current time step based at least on the set of predictions.

12. The at least one processor of claim 11, wherein the operations further comprise:
generating, via execution of the one or more neural networks, one or more additional states associated with a next time step following the current time step;
computing one or more losses based at least on the set of predictions, the one or more states, and the one or more additional states; and
updating one or more parameters of the one or more neural networks based at least on the one or more losses.

13. The at least one processor of claim 12, wherein the updating the one or more parameters of the one or more neural networks comprises:
computing a first loss based at least on the set of predictions and a set of ground truth observations associated with the current time step;
updating a first set of parameters included in the one or more neural networks based at least on the first loss;
computing a second loss between a prior distribution associated with the one or more additional states and a posterior distribution associated with the one or more states; and
updating a second set of parameters included in the one or more neural networks based at least on the second loss.

14. The at least one processor of claim 13, wherein the updating the one or more parameters of the one or more neural networks further comprises after the first set of parameters and the second set of parameters have been updated, updating a third set of parameters included in the one or more neural networks based at least on a third loss that is computed between one or more actions generated based at least on the third set of parameters and one or more additional actions associated with a teacher policy.

15. The at least one processor of claim 13, wherein:
the first set of parameters is included in a posterior estimator neural network and one or more encoder neural networks; and
the second set of parameters is included in a prior estimator neural network.

16. The at least one processor of claim 11, wherein the converting the set of sensory inputs into the set of embedded features comprises:
converting, via execution of one or more encoder neural networks, each sensory input included in the set of sensory inputs into a different embedding; and
combining the different embeddings of the set of sensory inputs into an input embedding associated with the set of sensory inputs.

17. The at least one processor of claim 11, wherein the machine comprises at least one of a quadruped robot, a humanoid robot, a differential drive system, an Ackermann drive system, a warehouse robot, or a forklift.

18. The at least one processor of claim 11, wherein the at least one processor is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system for generating or presenting at least one of virtual reality content, augmented reality content, or mixed reality content;
a system implemented using a robot;
a system for performing one or more conversational AI operations;
a system for performing one or more generative AI operations;
a system implementing one or more large language models (LLMs);
a system implementing one or more vision language models (VLMs);
a system implementing one or more multimodal language models;
a system for generating synthetic data;
a system incorporating one or more virtual machines (VMs);
a system implemented at least partially in a data center; or
a system implemented at least partially using cloud computing resources.

19. A system comprising:
one or more processors to cause one or more actions to be performed by a machine based at least on one or more states outputted using a generative world model, the one or more states being generated based on at least one of a set of sensory inputs received using the machine, a history of states associated with the machine, or one or more previous actions performed by the machine.

20. The system of claim 19, wherein the system is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system for generating or presenting at least one of virtual reality content, augmented reality content, or mixed reality content;
a system implemented using a robot;
a system for performing one or more conversational AI operations;
a system for performing one or more generative AI operations;
a system implementing one or more large language models (LLMs);
a system implementing one or more vision language models (VLMs);
a system implementing one or more multimodal language models;
a system for generating synthetic data;
a system incorporating one or more virtual machines (VMs);
a system implemented at least partially in a data center, or
a system implemented at least partially using cloud computing resources.
